(19) United States
(12) Patent Application Publication
(10) Pub. No.: US 2019/0081076 A1
(43) Pub. Date: Mar. 14, 2019

(54) THIN FILM TRANSISTOR SUBSTRATE AND DISPLAY PANEL

(71) Applicant: Sharp Kabushiki Kaisha, Sakai City, Osaka (JP)

(72) Inventors: Kuniaki OKADA, Sakai City (JP); Seiichi UCHIDA, Sakai City (JP); Naoki UEDA, Sakai City (JP); Takahiro SASAKI, Sakai City (JP)

(21) Appl. No.: 16/081,502

(22) PCT Filed: Feb. 28, 2017
(86) PCT No.: PCT/JP2017/007681

§ 371 Date: Aug. 31, 2018

(30) Foreign Application Priority Data
Mar. 4, 2016 (JP) 2016-041967

(51) Int. Cl. H01L 27/12; G02F 1/1362; G02F 1/1368; G02F 1/1343

(52) U.S. Cl. CPC H01L 27/124; H01L 27/1225; G02F 1/136286; G02F 2201/123; G02F 1/134309; G02F 1/136209; G02F 2201/121; G02F 1/1368

(57) ABSTRACT

An array substrate (thin film transistor substrate) 11b includes a source line (line) 20, a TFT (thin film transistor) 17 including a plurality of electrodes 17a, 17b, and 17c, and a line connector 31 made of light-transmitting conductive material and connected to the source line 20. At least a portion of the line connector 31 includes one of electrodes 17a, 17b, and 17c.

### TECHNICAL FIELD

The present invention relates to a thin film transistor substrate and a display panel.

### BACKGROUND ART

Heretofore, liquid crystal display devices such as the one described in Patent Document 1 specified below have been known. The liquid crystal display device described in Patent Document 1 is equipped with a thin film transistor substrate, wherein a source region is formed by a source metal provided to a layer above a gate insulation film and an oxide semiconductor film, while a drain region is formed by a low resistance region of the oxide semiconductor film that is a part of the oxide semiconductor film including a surface opposite from a gate region and having a reduced resistance.

### RELATED ART DOCUMENT

### Patent Document

Patent Document 1: Japanese Patent No. 5330603

### Problem to be Solved by the Invention

In the liquid crystal display device described in Patent Document 1 specified above, the source region extends from a source line made of source metal toward the thin film transistor. Since this source region is made of same source metal that forms the source line, it is an opaque region in a pixel and causes a reduction in the aperture ratio and a limitation in achieving a higher resolution.

### DISCLOSURE OF THE PRESENT INVENTION

The present invention was completed based on the circumstances described above and it is an object of the present invention to increase the aperture ratio. Means for Solving the Problem

A thin film transistor substrate of the present invention may include: a line; a thin film transistor including a plurality of electrodes; and a line connector made of light-transmitting conductive material and connected to the line. The line connector inludes at least a portion forming one of the plurality of electrodes.

The signal transmitted through the line is thus supplied via the line connector connected to the line to one of the electrodes includes in the thin film transistor that is configured by a portion of the line connector. Since the line connector is made of light-transmitting conductive material, the amount of light transmission is increased as compared to a configuration in which the line connector is made of light-shielding material such as metal and the aperture ratio is increased. The configuration is preferable for achieving a higher definition.

The following configurations are preferable as embodiments of the present invention.

(1) The thin film transistor substrate may further include: a first transparent electrode constructed from a first transparent electrode film and connected to one of the plurality of electrodes of the thin film transistor; and a second transparent electrode constructed from a second transparent electrode film overlapping the first transparent electrode film via an interlayer insulation film and configured to form a capacitor or an electric field between the second transparent electrode and the first transparent electrode. The line connector may be constructed from one of the first transparent electrode film and the second transparent electrode film. With the line connector constructed from the first transparent electrode film or second transparent electrode film that is a light-transmitting, conductive material, the aperture ratio can thus be increased sufficiently. The first transparent electrode or second transparent electrode and the line connector can be formed by patterning the first transparent electrode film or second transparent electrode film during the production of this thin film transistor substrate. This enables a reduction in the production costs.

(2) The thin film transistor may include a channel constructed from a semiconductor film. The plurality of electrodes may include: a source electrode including at least a portion of the line connector and connected to a first end of the channel; and a drain electrode that is connected to a second end of the channel. The drain electrode may be constructed from one of the first transparent electrode film and the second transparent electrode film from which the line connector is constructed. With the drain electrode constructed from the first transparent electrode film or second transparent electrode film that is a light-transmitting conductive material, the amount of light transmission is thus increased as compared to a configuration in which the drain electrode were made of light-shielding material such as metal and the aperture ratio is increased. Moreover, the drain electrode can also be formed in addition to the first transparent electrode or second transparent electrode and the line connector by patterning the first transparent electrode film or second transparent electrode film during the production of this thin film transistor substrate. This enables a further reduction in the production costs.

(3) The thin film transistor may include a channel constructed from an oxide semiconductor film. The plurality of electrodes may include: a source electrode including at least a portion of the line connector and connected to one end of the channel; and a drain electrode that is connected to a second end of the channel. The drain electrode may include a low resistance region that is a part of the oxide semiconductor film having a reduced resistance. With the drain electrode formed by a low resistance region that is a part of the oxide semiconductor film made of light-transmitting conductive material and having a reduced resistance, the amount of light transmission is thus increased as compared to if the drain electrode were made of light-shielding material such as metal, as a result of which the aperture ratio can be further increased. The drain electrode can also be formed in addition to the channel by patterning the oxide semiconductor film during the production of this thin film transistor substrate. This enables a further reduction in the production costs. Moreover, since the drain electrode is formed by a low resistance region of the oxide semiconductor film while the source electrode is constructed from the first transparent electrode film or second transparent electrode film, the distance that needs to be secured between a drain electrode and a source electrode can be set shorter as compared to when the drain electrode and source electrode were constructed from the same transparent electrode film. The channel can therefore be made shorter, so that the characteristics of the thin film transistor can be improved.

(4) The first transparent electrode may be a pixel electrode partly overlapping the line connector. The second transparent electrode may be an auxiliary capacitance electrode that forms a capacitor between the second transparent electrode and the pixel electrode to hold a potential charged at the pixel electrode. The line connector may be constructed from the second transparent electrode film. With the line connector constructed from the same second transparent electrode film that forms the auxiliary capacitance electrode, a configuration can be adopted wherein the pixel electrode constructed from the first transparent electrode film overlaps the line connector. This way, the pixel electrode can be formed in a wider area, so that the aperture ratio can be increased.

(5) The thin film transistor may include a channel constructed from an oxide semiconductor film. The plurality of electrodes may include: a source electrode that is at least a portion of the line connector and connected to a first end of the channel; and a drain electrode that is connected to a second end of the channel. The line connector may be formed by a low resistance region that is a part of the oxide semiconductor film having a reduced resistance. With the line connector formed by a low resistance region that is a part of the oxide semiconductor film made of light-transmitting conductive material and having a reduced resistance, the aperture ratio can thus be increased sufficiently. The channel and the line connector can both be formed by patterning the oxide semiconductor film during the production of this thin film transistor substrate. This enables a reduction in the production costs.

(6) The thin film transistor substrate may further include: a first transparent electrode constructed from a first transparent electrode film and connected to the drain electrode of the thin film transistor; and a second transparent electrode constructed from a second transparent electrode film overlapping the first transparent electrode film via an interlayer insulation film, and configured to form a capacitor or an electric field between the second transparent electrode and the first transparent electrode. The drain electrode may be constructed from one of the first transparent electrode film and the second transparent electrode film. With the drain electrode constructed from the first transparent electrode film or second transparent electrode film that is a light-transmitting, conductive material, the amount of light transmission is thus increased as compared to if the drain electrode were made of light-shielding material such as metal, as a result of which the aperture ratio is increased. The first transparent electrode or second transparent electrode and the drain electrode can both be formed by patterning the first transparent electrode film or second transparent electrode film during the production of this thin film transistor substrate. This enables a further reduction in the production costs. Moreover, since the drain electrode is constructed from the first transparent electrode film or second transparent electrode film while the source electrode is formed by a low resistance region of the oxide semiconductor film, the distance that needs to be secured between a drain electrode and a source electrode can be set shorter as compared to when the drain electrode and source electrode were constructed from the same transparent electrode film. The channel can therefore be made shorter, so that the characteristics of the thin film transistor can be improved.

(7) The drain electrode may include a low resistance region that is a part of the oxide semiconductor film having a reduced resistance. With the drain electrode and the source electrode of the line connector both formed by low resistance regions of the oxide semiconductor film, the distance that needs to be secured between a drain electrode and a source electrode can thus be set shorter as compared to if the drain electrode and source electrode were constructed from the same transparent electrode film. The channel can therefore be made shorter, so that the characteristics of the thin film transistor can be improved.

(8) The thin film transistor may include a channel constructed from a semiconductor film. The plurality of electrodes may include the source electrode that is at least a portion of the line connector and connected to the first end of the channel; and the drain electrode that is connected to the second end of the channel. The thin film transistor substrate may further include an insulation film disposed on an upper side of the semiconductor film and having holes formed in positions respectively overlapping the source electrode and the drain electrode. With the source electrode and drain electrode constructed from the transparent electrode film disposed on the upper side of the insulation film, for example, the source electrode and drain electrode are connected to the channel constructed from the semiconductor film respectively through the two holes formed in the insulation film. Alternatively, for example, if the semiconductor film is an oxide semiconductor film and the source electrode and drain electrode are formed by low resistance regions that are parts of the oxide semiconductor film having a reduced resistance, the resistance of the oxide semiconductor film may be reduced through the two holes formed in the insulation film, which allows for formation of a source electrode and a drain electrode connected to the channel. Either way, the length of the channel is determined by the distance between the two holes formed in the insulation film, so that the length of the channel is less likely to vary, which helps the thin film transistor exhibit its characteristics consistently.

(9) The thin film transistor substrate may further include a plurality of pixels having the thin film transistor and aligned at least along a direction in which the line connector extends from the line toward the thin film transistor. The hole of the insulation film overlapping the source electrode may extend across an area between pixels adjacent to each other in a direction in which the one of the holes extends. If the holes were formed in the insulation film discretely for the plurality of pixels aligned along the extending direction of the line connector in the same number as that of the pixels, it would be necessary to set a constant interval between adjacent holes. Such an interval need not be set if the hole that overlaps a source electrode extends in the area over the pixels adjacent to each other in the extending direction of the line connector. The array pitch of the pixels can thus be made smaller, which is favorable for achieving a higher resolution.

To solve the problems described above, a display panel of the present invention may include the thin film transistor substrate described above, and a counter substrate bonded to the thin film transistor substrate. The display panel with such a configuration is favorable for achieving a higher resolution because the aperture ratio of the thin film transistor substrate is made higher.

### Advantageous Effect of the Invention

According to the present invention, the aperture ratio can be increased.

### BRIEF DESCRIPTION OF THE DRAWINGS

FIG. 1 is a schematic plan view illustrating a connection configuration between a liquid crystal panel equipped with a driver according to a first embodiment of the present invention, a flexible board, and a control circuit board;

FIG. 2 is a schematic cross-sectional view illustrating a cross-sectional configuration along a long side direction of a liquid crystal display device;

FIG. 3 is a schematic cross-sectional view illustrating a cross-sectional configuration in a display area of the liquid crystal panel;

FIG. 4 is a plan view schematically illustrating a plan configuration in the display area of an array substrate that forms a part of the liquid crystal panel;

FIG. 5 is an enlarged plan view illustrating a plan configuration in the display area of a CF substrate that forms a part of the liquid crystal panel;

FIG. 6 is an A-A cross-sectional view of FIG. 4;

FIG. 7 is a B-B cross-sectional view of FIG. 4;

FIG. 8 is an A-A cross-sectional view of FIG. 4 illustrating a state where a first interlayer insulation film has been formed in a first interlayer insulation film forming step of a method of producing the array substrate;

FIG. 9 is a B-B cross-sectional view of FIG. 4 illustrating the state where the first interlayer insulation film has been formed in the first interlayer insulation film forming step of the method of producing the array substrate;

FIG. 10 is an A-A cross-sectional view of FIG. 4 illustrating a state where the first interlayer insulation film formed in the first interlayer insulation film forming step of the method of producing the array substrate has been patterned;

FIG. 11 is a B-B cross-sectional view of FIG. 4 illustrating the state where the first interlayer insulation film formed in the first interlayer insulation film forming step of the method of producing the array substrate has been patterned;

FIG. 12 is an A-A cross-sectional view of FIG. 4 illustrating a state where a first transparent electrode film formed in a first transparent electrode film forming step of the method of producing the array substrate has been patterned;

FIG. 13 is a B-B cross-sectional view of FIG. 4 illustrating the state where the first transparent electrode film formed in the first transparent electrode film forming step of the method of producing the array substrate has been patterned;

FIG. 14 is a plan view schematically illustrating a plan configuration in a display area of an array substrate that forms a part of a liquid crystal panel according to a second embodiment of the present invention;

FIG. 15 is a B-B cross-sectional view of FIG. 14;

FIG. 16 is a plan view schematically illustrating a plan configuration in a display area of an array substrate that forms a part of a liquid crystal panel according to a third embodiment of the present invention;

FIG. 17 is an A-A cross-sectional view of FIG. 16;

FIG. 18 is a B-B cross-sectional view of FIG. 16;

FIG. 19 is an A-A cross-sectional view of FIG. 16 in which the length of the channel has been changed;

FIG. 20 is a schematic cross-sectional view illustrating a cross-sectional configuration in a display area of a liquid crystal panel according to a fourth embodiment of the present invention;

FIG. 21 is a plan view schematically illustrating a plan configuration in the display area of an array substrate that forms a part of the liquid crystal panel;

FIG. 22 is an A-A cross-sectional view of FIG. 21;

FIG. 23 is a B-B cross-sectional view of FIG. 21;

FIG. 24 is an A-A cross-sectional view of FIG. 21 illustrating a state where a first interlayer insulation film has been patterned in a first interlayer insulation film forming step of a method of producing the array substrate;

FIG. 25 is a B-B cross-sectional view of FIG. 21 illustrating a state where the first interlayer insulation film has been patterned in the first interlayer insulation film forming step of the method of producing the array substrate;

FIG. 26 is an A-A cross-sectional view of FIG. 21 illustrating a state where a second interlayer insulation film has been formed in a second interlayer insulation film forming step of the method of producing the array substrate;

FIG. 27 is a B-B cross-sectional view of FIG. 21 illustrating the state where the second interlayer insulation film has been formed in the second interlayer insulation film forming step of the method of producing the array substrate;

FIG. 28 is an A-A cross-sectional view of FIG. 21 illustrating a state where a first transparent electrode film formed in a first transparent electrode film forming step of the method of producing the array substrate has been patterned;

FIG. 29 is a B-B cross-sectional view of FIG. 21 illustrating the state where the first transparent electrode film formed in the first transparent electrode film forming step of the method of producing the array substrate has been patterned;

FIG. 30 is a plan view schematically illustrating a plan configuration in a display area of an array substrate that forms a part of a liquid crystal panel according to a fifth embodiment of the present invention;

FIG. 31 is a B-B cross-sectional view of FIG. 30;

FIG. 32 is a plan view schematically illustrating a plan configuration in a display area of an array substrate that forms a part of a liquid crystal panel according to a sixth embodiment of the present invention;

FIG. 33 is an A-A cross-sectional view of FIG. 32;

FIG. 34 is a B-B cross-sectional view of FIG. 32;

FIG. 35 is a plan view schematically illustrating a plan configuration in a display area of an array substrate that forms a part of a liquid crystal panel according to a seventh embodiment of the present invention;

FIG. 36 is an A-A cross-sectional view of FIG. 35;

FIG. 37 is a B-B cross-sectional view of FIG. 35;

FIG. 38 is a plan view schematically illustrating a plan configuration in a display area of an array substrate that forms a part of a liquid crystal panel according to an eighth embodiment of the present invention;

FIG. 39 is a B-B cross-sectional view of FIG. 38;

FIG. 40 is a plan view schematically illustrating a plan configuration in a display area of an array substrate that forms a part of a liquid crystal panel according to a reference example;

FIG. 41 is an A-A cross-sectional view of FIG. 40; and

FIG. 42 is a B-B cross-sectional view of FIG. 40.

### MODE FOR CARRYING OUT THE INVENTION

### First Embodiment

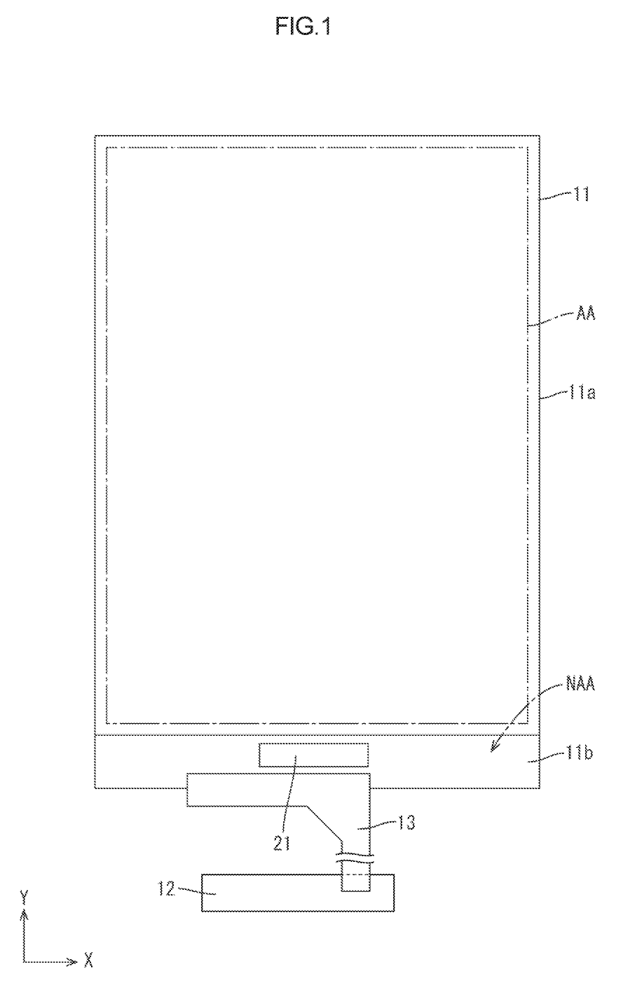

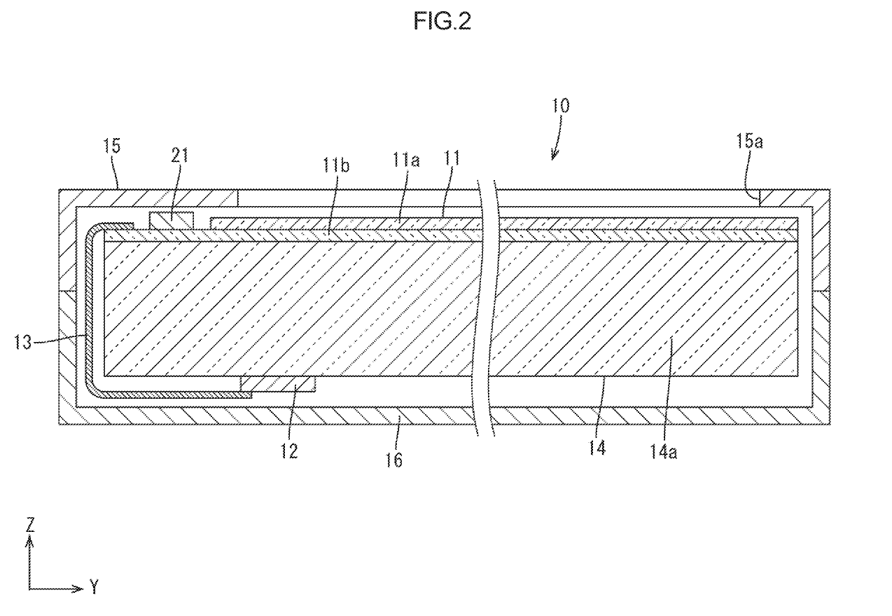

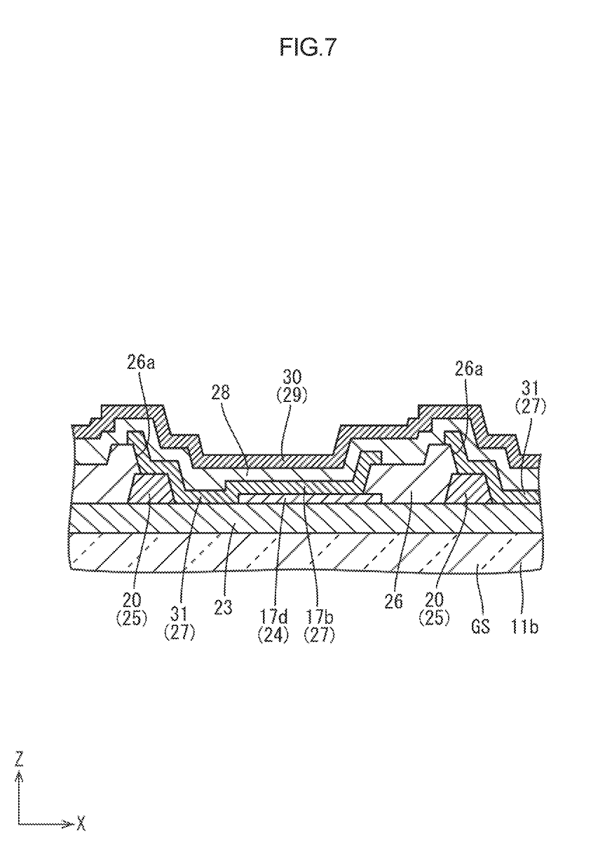

A first embodiment of the present invention will be described with reference to FIGS. 1 to 13. The present embodiment illustrates a liquid crystal display device 10. Some of the drawings show X-, Y-, and Z-axes, which are drawn such that the respective axis directions correspond to the directions indicated in each of the drawings. The upper side in FIGS. 2 and 7 and others shall be the front side, and the lower side in these drawings shall be the backside.

The liquid crystal display device 10 has a horizontal quadrilateral shape as a whole. As shown in FIGS. 1 and 2, the device at least includes a liquid crystal panel (display panel) 11 configured to display images, a control circuit board (panel connecting board) 12 that supplies various input signals to the liquid crystal panel 11 from outside, a flexible board 13 that electrically connects the liquid crystal panel 11 and the control circuit board 12, and a backlight device (illumination device) 14 that is an external light source and supplies light to the liquid crystal panel 11. The liquid crystal display device 10 further includes, as shown in FIG. 2, a bezel 15 and a casing 16 for housing and holding the liquid crystal panel 11 and backlight device 14 assembled together. The bezel 15 forms a frame shape surrounding a display area (active area) AA of the liquid crystal panel 11 where images are displayed. The casing 16 has a shallow box-like shape open on the front side.

The backlight device 14 will be described briefly first. The backlight device 14 at least includes, as shown in FIG. 2, a substantially box-shaped chassis 14a open on the front side (liquid crystal panel 11 side), a light source (not shown) disposed inside the chassis 14a (such as a cold-cathode tube, LED, organic EL, and so on), and an optical component (not shown) disposed such as to cover the hole of the chassis 14a. The optical component has a function of converting the light emitted from the light source into planar light beams.

Next, the liquid crystal panel 11 will be described. The liquid crystal panel 11 has a vertical quadrilateral (rectangular) shape as a whole as shown in FIG. 1, with the display area (active area) AA disposed in a position closer to one end in the long side direction (upper side shown in FIG. 1). A driver 21 and the flexible board 13 are each attached in positions closer to the other end in the long side direction (lower side shown in FIG. 1). The region outside the display area AA of this liquid crystal panel 11 is a non-display area (non-active area) NAA where images are not shown. The short side direction of the liquid crystal panel 11 corresponds to the X-axis direction of each drawing, and the long side direction corresponds to the Y-axis direction of each drawing. In FIG. 1, the rectangle indicated by one-dot chain lines represents the outer shape of the display area AA, which is smaller than the CF substrate 11a. The region outside these one-dot chain lines is the non-display area NAA.

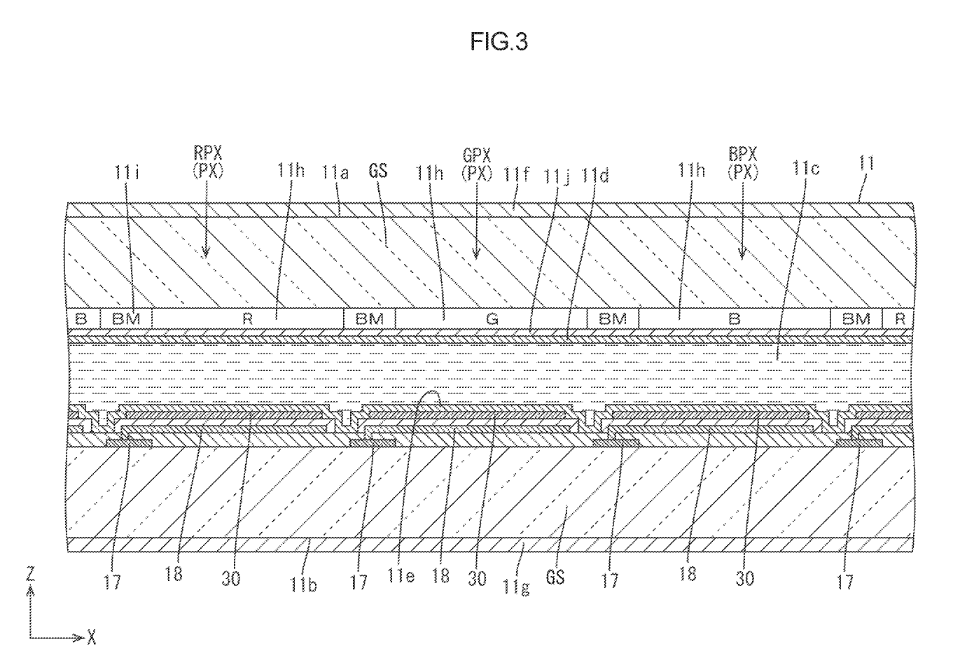

As shown in FIG. 3, the liquid crystal panel 11 at least includes a pair of substrates 11a and 11b and a liquid crystal layer 11c sandwiched between substrates 11a and 11b. The liquid crystal layer 11 is made of liquid crystal material having optical characteristics that vary according to application of electric fields. The substrates 11a and 11b are bonded together with a sealant (not shown) with the gap corresponding to the thickness of the liquid crystal layer 11c maintained therebetween. One of the substrates 11a and 11b on the front (front side) is a CF substrate (counter substrate) 11a, while the other of the substrates 11a and 11b on the back (backside) is an array substrate (thin film transistor substrate, active matrix substrate) 11b. The CF substrate 11a and array substrate 11b include substantially transparent (light-transmitting) glass substrates GS including inner surfaces on which various films are formed in layers. Orientation films 11d and 11e for orienting the liquid crystal material (liquid crystal molecules LC) that forms the liquid crystal layer 11c are formed respectively on the inner side surfaces of both substrates 11a and 11b facing the liquid crystal layer 11c. Polarization plates 11f and 11g are bonded respectively on the outer side surfaces of both

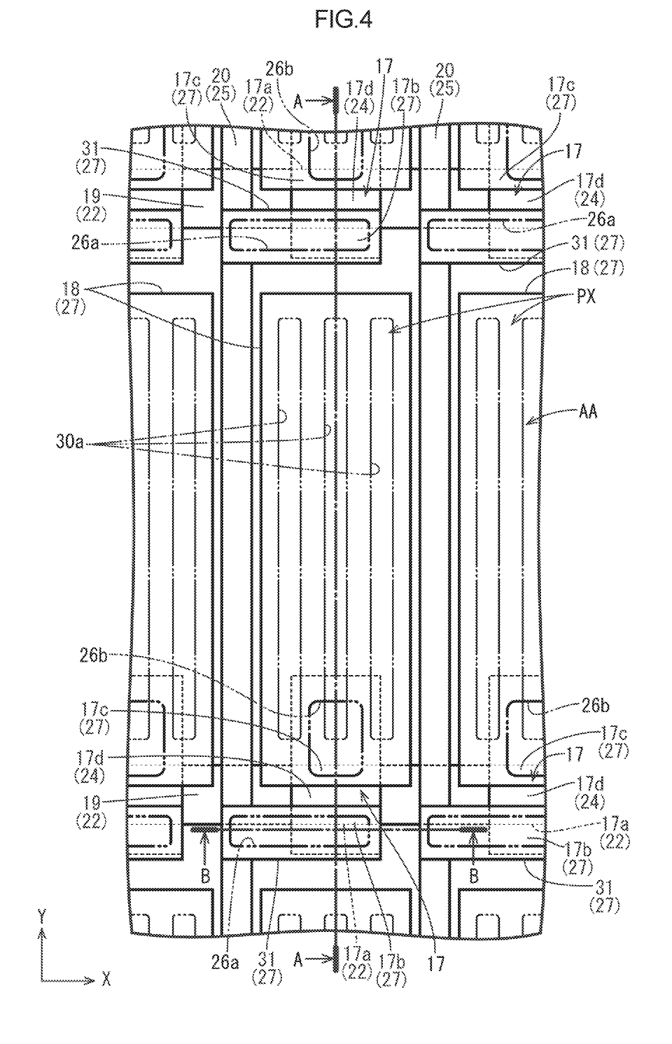

Next, the structural components within the display area AA of the array substrate 11b and CF substrate 11a will be described one after another in detail. As shown in FIGS. 3 and 4, a large number of TFTs (thin film transistors) 17 that are switching devices, and pixel electrodes (first transparent electrodes) 18 are arranged in a matrix on the inner side face of the array substrate 11b (on the side facing the liquid crystal layer 11c, opposite the CF substrate 11a). A grid of gate lines (row control lines, or scan lines) 19 and source lines (column control lines, data lines, or lines) 20 are arranged such as to surround each of these TFTs 17 and pixel electrodes 18. In other words, the TFTs 17 and pixel electrodes 18 are formed at intersections of the grid of gate lines 19 and source lines 20 such that they are arranged in rows (X-axis direction) and columns (Y-axis direction), i.e., in a matrix. The gate lines 19 extend straight along the X-axis direction, while the source lines 20 extend straight along the Y-axis direction, i.e., the X-axis direction and Y-axis direction respectively correspond to the extending directions of the gate lines 19 and source lines 20. Specific structures of the TFT 17 and pixel electrode 18 will be described in more detail later.

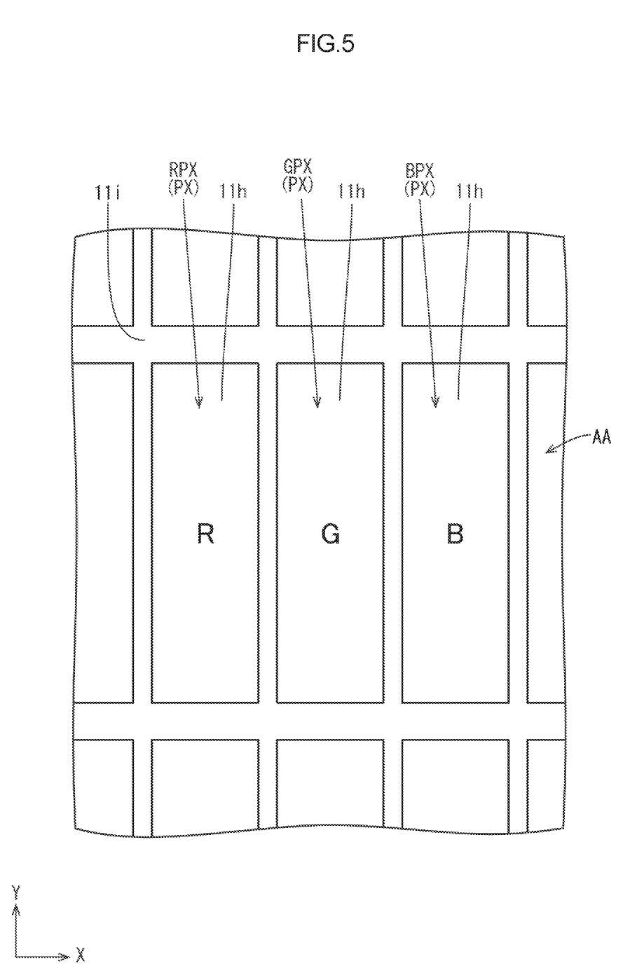

As shown in FIGS. 3 and 5, color filters 11h having coloring units of three colors, red (R), green (G), and blue (B) are provided on the inner side face of the CF substrate 11a (on the side facing the liquid crystal layer 11c, opposite the array substrate 11b). A plurality each of coloring units that form the color filters 11h are arranged in rows (X-axis direction) and columns (Y-axis direction), i.e., in a matrix, each overlapping each of the pixel electrodes 18 on the array substrate 11b side when viewed in plan. A substantially grid-like light shield (black matrix) 11i is formed between adjacent coloring units that form the color filters 11h to avoid mixing of colors. The light shield 11i is arranged to overlap the gate lines 19 and source lines 20 described above when viewed in plan. The light shield 11i is made of material having light shielding properties such as titanium (Ti), for example, and should preferably have a film thickness of about 200 nm, for example. A continuous overcoat film 11j made of synthetic resin is superposed on the inner surfaces of the color filters 11h and light shield 11i. In this liquid crystal panel 11, as shown in FIGS. 3 to 5, a unit of three coloring units of three colors R, G, and B in the color filters 11h, three pixel electrodes 18 opposite each coloring units, and three TFTs 17 each connected to the pixel electrodes 18 forms one pixel PX, which is a display unit. Pixels PX include red pixels RPX having red coloring units, green pixels GPX having green coloring units, and blue pixels BPX having blue coloring units. These pixels of respective colors RPX, GPX, and BPX are periodically arranged along the row direction (X-axis direction) on the plate surface of the liquid crystal panel 11 to form a group of pixels, and a large number of these groups of pixels are aligned along the column direction (Y-axis direction).

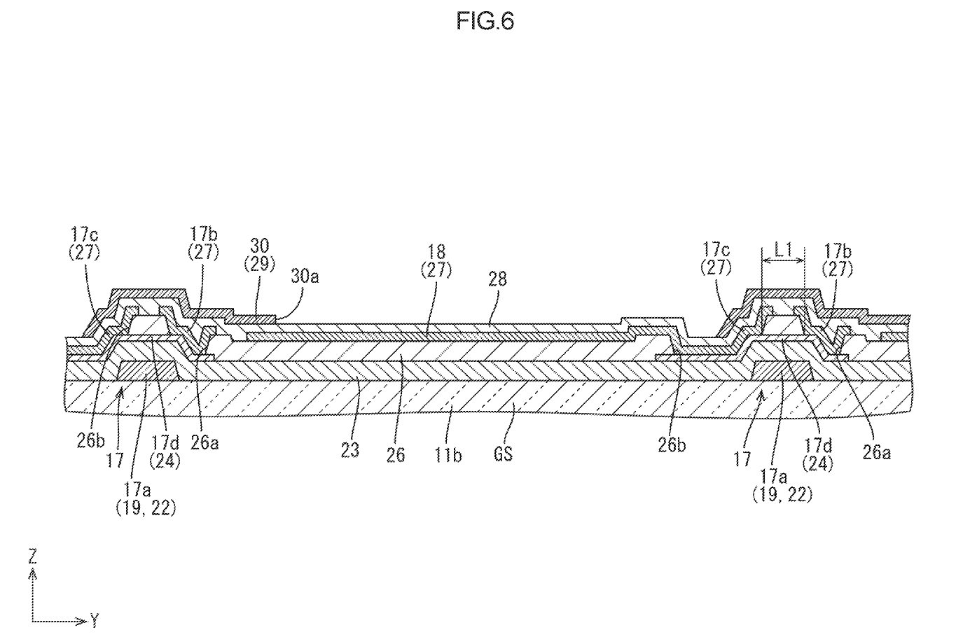

Various films are formed upon one another by known photolithography techniques on the inner face of the array substrate 11b. These films will now be described. On the array substrate 11b, as shown in FIGS. 6 and 7, there are formed, in the order from the lower layer (glass substrate GS), a first metal film (gate metal film, lower metal film) 22, a gate insulation film 23, an oxide semiconductor film (semiconductor film) 24, a second metal film (source metal film, upper metal film) 25, a first interlayer insulation film (insulation film, lower insulation film) 26, a first transparent electrode film (lower transparent electrode film) 27, a second interlayer insulation film (interlayer insulation film, upper insulation film) 28, and a second transparent electrode film (upper transparent electrode film) 29. FIGS. 6 and 7 do not show the orientation film 11e stacked further on the upper side of the second transparent electrode film 29.

The first metal film 22 is a two-layer stack of metal such as tungsten (W) layer/tantalum nitride (TaN) layer, for example. The tungsten layer should preferably have a film thickness of about 300 nm, for example, and the tantalum nitride layer should preferably have a film thickness of about 30 nm, for example. The first metal film 22 primarily forms the gate lines 19. The gate insulation film 23 is formed on the upper side of the first metal film 22 as shown in FIGS. 6 and 7. The gate insulation film 23 is a stack of inorganic materials such as silicon oxide (SiO₂) layer/silicon nitride (SiNₓ) layer, for example. The silicon oxide layer should preferably have a film thickness of about 50 nm, for example, and the silicon nitride layer should preferably have a film thickness of about 325 nm, for example. The gate insulation film 23 is interposed between the first metal film (gate lines 19 and the like) 22 and the second metal film 25 (source lines 20 and the like) to be described later and provides insulation from each other.

The oxide semiconductor film 24, which is a thin film constructed from an oxide semiconductor, is stacked on the upper side of the gate insulation film 23 as shown in FIGS. 6 and 7. The oxide semiconductor film 24 should preferably have a film thickness of about 50 nm, for example. The oxide semiconductor contained in the oxide semiconductor film 24 may be an amorphous oxide semiconductor, or a crystalline oxide semiconductor having a crystalline structure. Crystalline oxide semiconductors include polycrystalline oxide semiconductors, microcrystalline oxide semiconductors, and c-axis aligned crystalline oxide semiconductors having the c-axis oriented substantially perpendicular to the surface. The oxide semiconductor film 24 may have a stacked structure of two or more layers. When the oxide semiconductor film 24 has a stacked structure, the oxide semiconductor film 24 may include an amorphous oxide semiconductor layer and a crystalline oxide semiconductor layer. Alternatively, the film may include a plurality of crystalline oxide semiconductor layers having different crystalline structures. Alternatively, the film may contain a plurality of amorphous oxide semiconductor layers. When the oxide semiconductor film 24 has a double layer structure including an upper layer and a lower layer, the oxide semiconductor contained in the upper layer should preferably have a larger energy gap than that of the oxide semiconductor contained in the lower layer. Provided that the difference in energy gap between these layers is relatively small, the oxide semiconductor contained in the lower layer may have a larger energy gap than that of the oxide semiconductor contained in the upper layer.

The materials, structures, and deposition methods of amorphous oxide semiconductors and various crystalline oxide semiconductors mentioned above, and the structures of oxide semiconductor films 24 having a stacked structure, are as described in Japanese Unexamined Patent Publication No. 2014-007399, for example. Japanese Unexamined Patent Publication No. 2014-007399 is herein entirely incorporated by reference. The oxide semiconductor film 24 may contain at least one of the group of metallic elements consisting of In, Ga, and Zn, for example. In the present embodiment, the oxide semiconductor film 24 contains an In—Ga—Zn—O semiconductor (e.g., indium gallium zinc oxide), for example. The In—Ga—Zn—O semiconductor is a ternary oxide of In (indium), Ga (gallium), and Zn (zinc) in various ratios (compositions) including, but not limited to, In:Ga:Zn=2:2:1, In:Ga:Zn=1:1:1, In:Ga:Zn=1:1:2, and so on. Such an oxide semiconductor film 24 can be formed by an oxide semiconductor film containing an In—Ga—Zn—O semiconductor. The In—Ga—Zn—O semiconductor may be amorphous, or crystalline. Crystalline In—Ga—Zn—O semiconductors should preferably be a c-axis aligned In—Ga—Zn—O semiconductor having the c-axis oriented substantially perpendicular to the surface.

The crystalline structures of crystalline In—Ga—Zn—O semiconductors are disclosed in Japanese Unexamined Patent Publication No. 2014-007399 mentioned above, and in Japanese Unexamined Patent Publication Nos. 2012-134475 and 2014-209727, for example. Japanese Unexamined Patent Publication Nos. 2012-134475 and 2014-209727 are herein entirely incorporated by reference. TFTs having In—Ga—Zn—O semiconductor layers have a high mobility (more than 20 times that of a-SiTFT) and a small leak current (less than one hundredth of that of a-SiTFT), and therefore are suitably used as drive TFTs that are not shown (e.g., TFTs contained in drive circuits provided on the same substrate as the display area around the display area containing a plurality of pixels), and as TFTs (TFTs provided to the pixels) 17.

The oxide semiconductor film 24 may contain other oxide semiconductors than the In—Ga—Zn—O semiconductor. For example, the film may contain an In—Sn—Zn—O semiconductor (e.g., In₂O₃—SnO₂—ZnO; InSnZnO). The In—Sn—Zn—O semiconductor is a ternary oxide of In (indium), Sn (tin), and Zn (zinc). Alternatively, the oxide semiconductor film 24 may contain an In—Al—Zn—O semiconductor, In—Al—Sn—Zn—O semiconductor, Zn—O semiconductor, In—Zn—O semiconductor, Zn—Ti—O semiconductor, Cd—Ge—O semiconductor, Cd—Pb—O semiconductor, CdO (cadmium oxide), Mg—Zn—O semiconductor, In—Ga—Sn—O semiconductor, In—Ga—O semiconductor, Zr—In—Zn—O semiconductor, Hf—In—Zn—O semiconductor, and the like.

The second metal film 25 is formed on the upper side of the oxide semiconductor film 24 as shown in FIGS. 6 and 7. The second metal film 25 is a three-layer stack of metal such as titanium (Ti) layer/aluminum (Al) layer/titanium layer, for example. The lower titanium layer should preferably have a film thickness of about 100 nm, for example, the aluminum layer should preferably have a film thickness of about 200 nm, for example, and the upper titanium layer should preferably have a film thickness of about 30 nm, for example. The second metal film 25 primarily forms the source lines 20. The first interlayer insulation film 26 is stacked on the upper side of at least the second metal film 25. The first interlayer insulation film 26 is made of inorganic material such as silicon oxide (SiO₂), for example, and should preferably have a film thickness of about 300 nm, for example. The first interlayer insulation film 26 is interposed between the second metal film 25 and oxide semiconductor film 24, and the first transparent electrode film 27, and insulates them from each other.

The first transparent electrode film 27 is formed on the second interlayer insulation film 28 as shown in FIGS. 6 and 7. The first transparent electrode film 27 is made of transparent electrode material such as IZO (indium zinc oxide), for example, and has a film thickness of about 100 nm, for example. The first transparent electrode film 27 primarily forms the pixel electrodes 18. The second interlayer insulation film 28 is stacked on the first transparent electrode film 27. The second interlayer insulation film 28 is made of inorganic material such as silicon nitride (SiN), for example, and should preferably have a film thickness of about 100 nm, for example. The second interlayer insulation film 28 is interposed between the first transparent electrode film 27 and the second transparent electrode film 29, and insulates them from each other. The second transparent electrode film 29 is stacked on the upper side of the second interlayer insulation film 28. The second transparent electrode film 29 is made of transparent electrode material such as IZO similarly to the first transparent electrode film 27, and has a film thickness of about 100 nm, for example. The second transparent electrode film 29 is continuously deposited such as to collectively cover the groups of pixels PX on the array substrate 11b, and forms a common electrode (second transparent electrode) 30 overlapped on the pixel electrodes 18 via the second interlayer insulation film 28. The continuous common electrode 30 has a plurality of slits 30a parallel to each other in portions overlapping the pixel electrodes 18 for each of pixels PX, so that diagonal electric fields are generated between the ends of slits 30a of the common electrode 30 and the pixel electrodes 18 based on the voltage applied to the pixel electrodes 18. Namely, the liquid crystal panel 11 according to the present embodiment operates in a so-called FFS (fringe-field switching) mode, wherein the diagonal electric field mentioned above is controlled based on the voltage applied to the pixel electrode 18 so as to control the orientation of the liquid crystal molecules contained in the liquid crystal layer 11c. In FIG. 4, areas where the slits 30a are formed are shown by relatively thin two-dot chain lines in comparison to source-side holes 26a and drain-side holes 26b.

The structure of the TFT 17 will now be described in detail. The TFT 17 includes three electrodes 17a to 17c and a channel 17d as shown in FIGS. 4 and 6. More specifically, the TFT 17 includes a gate electrode (electrode) 17a that is a part of the gate line 19, a channel 17d constructed from the oxide semiconductor film 24 and positioned above the gate electrode 17a to overlap it via the gate insulation film 23, a source electrode (electrode) 17b arranged on the upper side of the channel 17d and connected to a first end of the channel 17d, and a drain electrode (electrode) 17c connected to a second end of the channel 17d and the pixel electrode 18. The direction in which the source electrode 17b, channel 17d, and drain electrode 17c forming the TFT 17 are aligned corresponds to the Y-axis direction. The channel 17d, which forms the TFT 17, is connected to the source electrode 17b and drain electrode 17c at points aligned in a direction (extending direction of the channel 17d) extending along the Y-axis direction. Namely, the direction in which the source electrode 17b, channel 17d, and drain electrode 17c are aligned corresponds to the extending direction of the channel 17d. Therefore, the space for disposing the TFT 17 can be made smaller in the X-axis direction (extending direction of the gate lines 19), so that the array pitch of the pixels PX in the X-axis direction can be reduced, which is favorable for achieving a higher resolution.

More specifically, the TFT 17 is arranged substantially at a central position in the X-axis direction of the pixel PX as shown in FIG. 4, and at the lower end position of the Y-axis direction as shown in FIG. 4. The gate electrode 17a that is a part of the TFT 17 is formed by a portion of the gate line 19 positioned below the pixel PX in FIG. 4, located between two source lines 20 defining the pixel PX. The gate line 19 is not protruded or recessed in the Y-axis direction from both side edges. The channel 17d overlaps the gate electrode 17a and extends along the Y-axis direction such that it is sandwiched between the source electrode 17b and the drain electrode 17c in the Y-axis direction. The channel 17d is formed by the oxide semiconductor film 24 in an island shape for each pixel PX. In the TFT 17 according to the present embodiment, no etch stop layer is formed on the channel 17d, so that the lower surface at one end of the source electrode 17b facing the channel 17d is disposed in contact with the upper surface of the oxide semiconductor film 24.

The source electrode 17b is positioned such as to partly overlap the gate line 19 (gate electrode 17a) as shown in FIGS. 4 and 6. More specifically, the source electrode 17b is displaced relative to the gate line 19 to one side opposite from the pixel PX in the Y-axis direction to which it is connected. While a part of the source electrode 17b on the side closer to the drain electrode 17c overlaps the gate line 19 (gate electrode 17a), most of it extends out toward the adjacent pixel PX below in the Y-axis direction in FIG. 4. This source electrode 17b is a part of a line connector 31 connected to the source line 20 as shown in FIGS. 4 and 7. Accordingly, image signals (data signals) transmitted through the source line 20 are supplied to the source electrode 17b that is a part of the line connector 31 via the line connector 31 connected to the source line 20. The line connector 31 is constructed from the first transparent electrode film 27 from which the pixel electrodes 18 are constructed, i.e., the line connector is made of light-transmitting conductive material. According to such a configuration, the amount of light transmission in pixels PX is increased as compared to if the line connector were made of light-shielding material such as metal rather than a light transmitting material. Therefore, the aperture ratio per pixel PX increases. This is favorable for achieving a higher resolution. Moreover, the pixel electrodes 18 and line connectors 31 (source electrodes 17b) can both be formed by patterning the first transparent electrode film 27 during the production of the array substrate 11b. This enables a reduction in the production costs. The pixel electrode 18 constructed from the same first transparent electrode film 27 that forms the line connector 31 is arranged in a planar manner such as not to overlap the line connector 31 but to fill a vertical quadrilateral region when viewed in plan surrounded by two each gate lines 19 and source lines 20 defining the area where the pixel PX to which the pixel electrode belongs is formed.

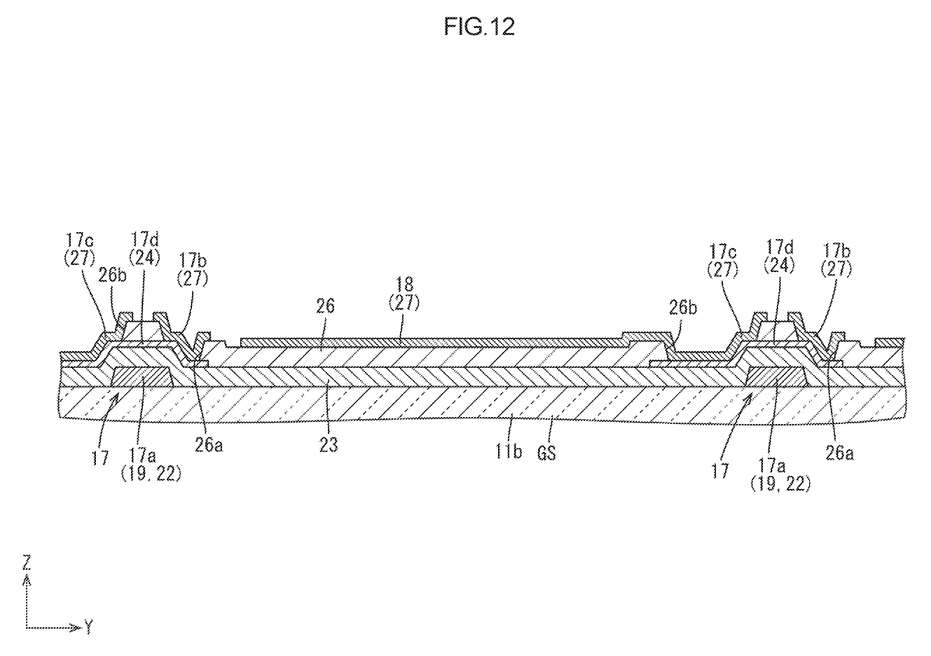

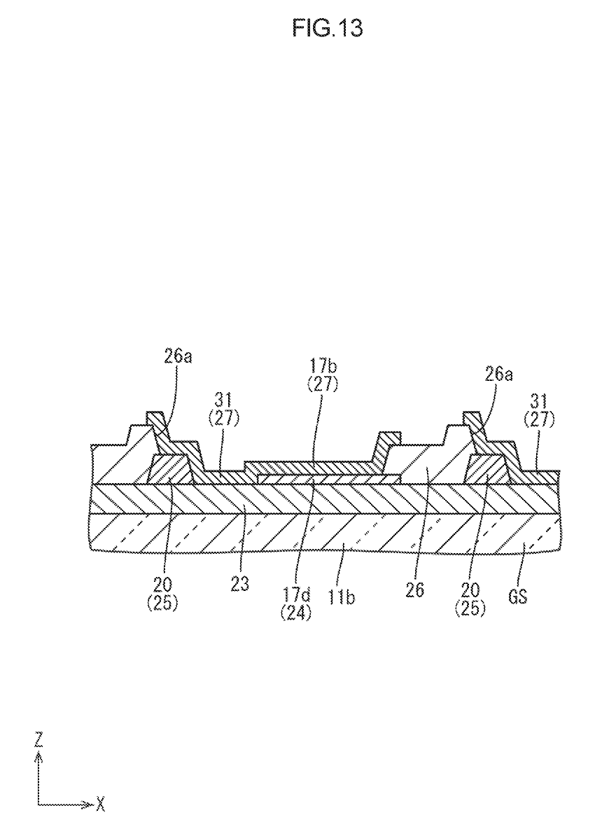

The drain electrode 17c partly overlaps the gate line 19 (gate electrode 17a) as shown in FIGS. 4 and 6 and faces the source electrode 17b with a gap corresponding to the channel 17d. This drain electrode 17c is constructed from the first transparent electrode film 27 from which the line connector 31 is constructed. More specifically, the drain electrode 17c is formed by a part of the pixel electrode 18 that is constructed from the first transparent electrode film 27. The image signal (potential) supplied to the source electrode 17b is supplied to the drain electrode 17c via the channel 17d when the gate electrode 17a is turned on. The pixel electrode 18 is charged by the image signal supplied to the drain electrode 17c. Since the drain electrode 17c is constructed from the first transparent electrode film 27 that is a light-transmitting, conductive material as described above, the amount of light transmission in pixels PX is increased as compared to if the drain electrode were made of light-shielding material such as metal, as a result of which the aperture ratio per pixel PX is increased. Moreover, the drain electrodes 17c can be formed in addition to the pixel electrodes 18 and line connectors 31 by patterning the first transparent electrode film 27 during the production of the array substrate 11b (see FIGS. 12 and 13). This enables a further reduction in the production costs.

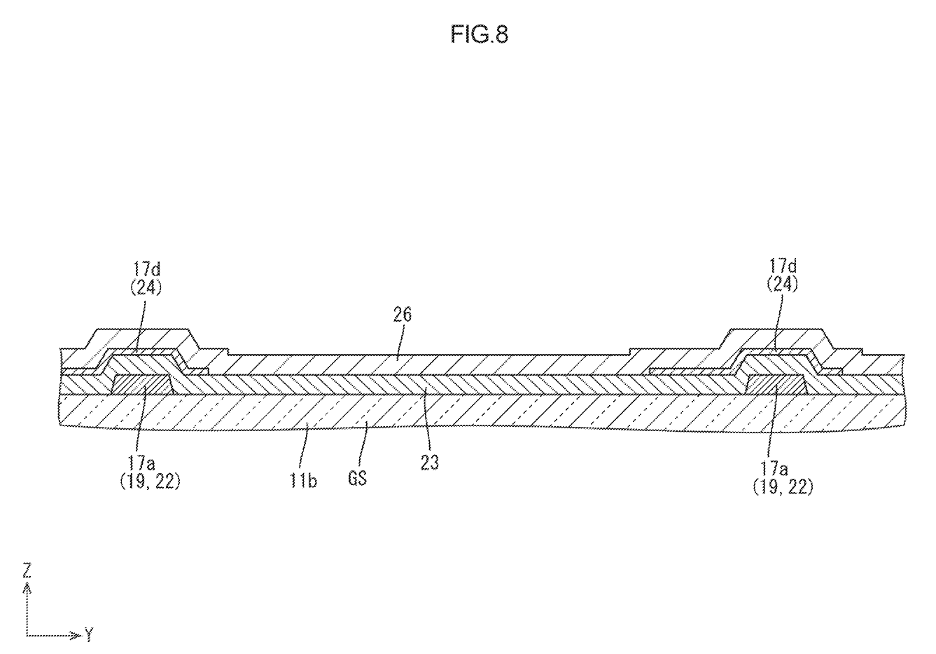

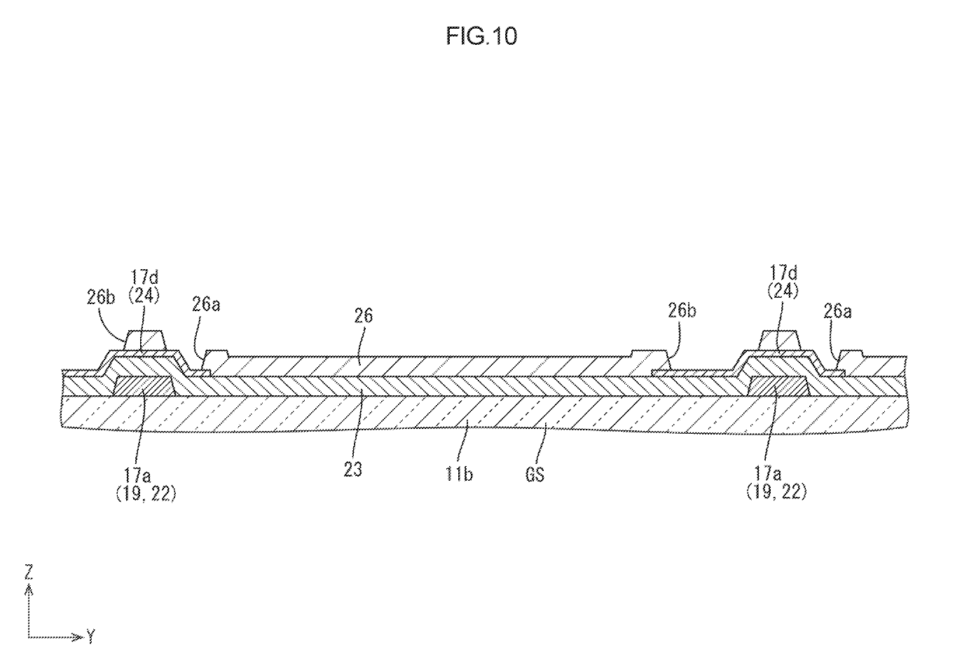

The source electrode 17b and drain electrode 17c configured as described above are connected to the channel 17d constructed from the oxide semiconductor film 24 respectively through two holes (contact holes) 26a and 26b formed in the first interlayer insulation film 26 positioned below the first transparent electrode film 27 and above the oxide semiconductor film 24 as shown in FIG. 6. The two holes 26a and 26b in the first interlayer insulation film 26 include a source-side hole 26a positioned near one end of the channel 17d where it overlaps the line connector 31 containing the source electrode 17b for the source electrode 17b to pass through, and a drain-side hole 26b positioned near the other end of the channel 17d where it overlaps the drain electrode 17c for the drain electrode 17c to pass through. Thus, the length of the channel 17d (channel length) L1 is defined by the distance between the source-side hole 26a and the drain-side hole 26b. Namely, the length L1 of the channel 17d is determined by the exposure accuracy of a photomask used in the step of patterning the first interlayer insulation film 26 (for forming at least two holes 26a and 26b) in the production process of the array substrate 11b. Therefore, the exposure accuracy and the like of photomasks in other steps will be substantially irrelevant to the length L1 of the channel 17d (see FIGS. 8 and 10). Thus, the length L1 of the channel 17d is less likely to vary, which helps the TFT 17 exhibit its characteristics consistently. FIG. 4 indicates areas where the source-side holes 26a and drain-side holes 26b are formed with relatively thick one-dot chain lines in comparison to the slits 30a.

The source-side hole 26a extends straight along the X-axis direction as shown in FIGS. 4 and 7 over an area from the source line 20 to one end of the channel 17d, which is substantially the entire length of the line connector 31 except for both ends in the length direction, so that it is a horizontal quadrilateral when viewed in plan. Thus the line connector 31 is stacked in direct contact with each of the source line 20 and one end of the channel 17d through the source-side hole 26a, and the portion positioned between the source line 20 and the channel 17d makes direct contact with the gate insulation film 23 through the source-side hole 26a. The lengthwise dimension of the source-side hole 26a (dimension in its extending direction) is smaller than the array pitch of the pixels PX. The same number of the source-side holes 26a as the number of pixels PX aligned on the plate surface of the array substrate 11b are arranged discretely for each of the pixels PX. As shown in FIGS. 4 and 6, the drain-side hole 26b is positioned at the other end of the channel 17d, more specifically in a portion overlapping the pixel electrode 18 (pixel electrode overlapping portion), and has a quadrilateral shape in plan view that is smaller than this pixel electrode overlapping portion. Thus the drain electrode 17c is stacked in direct contact with the pixel electrode overlapping portion of the channel 17d through the drain-side hole 26ba.

The liquid crystal panel 11 according to the present embodiment is configured as described above. Next, the method of producing the panel will be described. The liquid crystal panel 11 according to the present embodiment is produced by bonding together the CF substrate 11a and array substrate 11b that are fabricated separately. A production method of the array substrate 11b that is a part of the liquid crystal panel 11 will be described in detail below.

The method of producing the array substrate 11b at least includes a first metal film forming step of forming the first metal film 22 to provide the gate lines 19, gate electrodes 17a and so on, a gate insulation film forming step of forming the gate insulation film 23, a semiconductor film forming step of forming the oxide semiconductor film 24 to provide the channels 17d and so on, a second metal film forming step of forming the second metal film 25 to provide the source lines 20 and so on, a first interlayer insulation film forming step of forming the first interlayer insulation film 26 to provide the source-side holes 26a, drain-side holes 26b and so on, a first transparent electrode film forming step of forming the first transparent electrode film 27 to provide the pixel electrodes 18, source electrodes 17b, drain electrodes 17c and so on, a second interlayer insulation film forming step of forming the second interlayer insulation film 28, and a second transparent electrode film forming step of forming the second transparent electrode film 29 to provide the common electrode 30 and so on.

In the first metal film forming step included in the method of producing the array substrate 11b, the first metal film 22 and a photoresist are deposited on the glass substrate GS one after another, and gate lines 19, gate electrodes 17a and so on are formed by etching after exposing and developing the photoresist using a photomask. In the gate insulation film forming step, the gate insulation film 23 is formed continuously on the glass substrate GS and first metal film 22. In the semiconductor film forming step, the oxide semiconductor film 24 and a photoresist are deposited on the gate insulation film 23 one after another, and channels 17d and so on are formed by etching after exposing and developing the photoresist using a photomask. In the second metal film forming step, the second metal film 25 and a photoresist are deposited on the gate insulation film 23 and oxide semiconductor film 24 one after another, and source lines 20 and so on are formed by etching after exposing and developing the photoresist using a photomask.

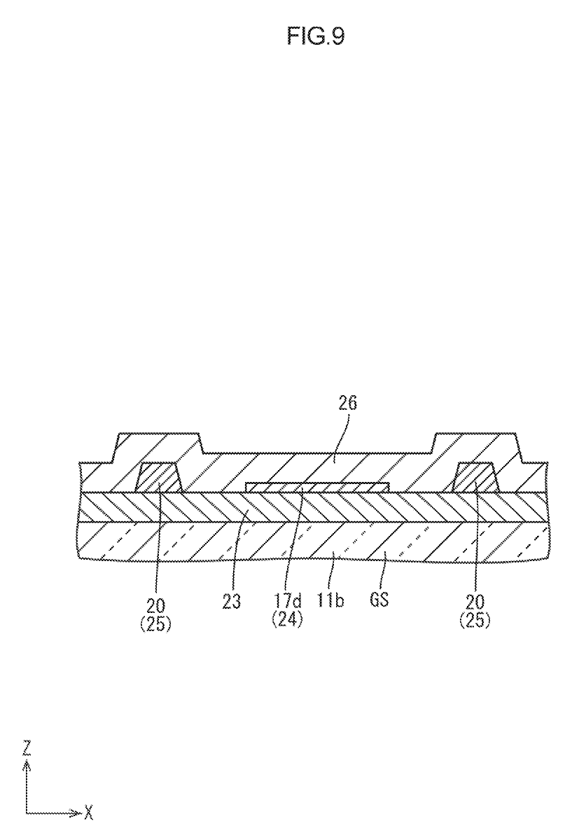

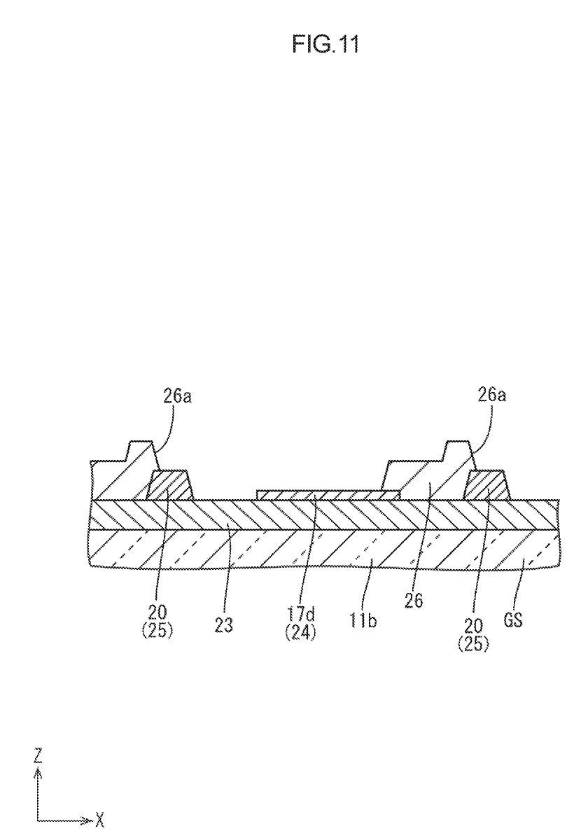

In the first interlayer insulation film forming step, as shown in FIGS. 8 and 9, the first interlayer insulation film 26 and a photoresist are deposited on the gate insulation film 23, oxide semiconductor film 24, and second metal film 25, and source-side holes 26a, drain-side holes 26b and so on are formed as shown in FIGS. 10 and 11 by etching after exposing and developing the photoresist using a photomask. Since the distance between the source-side hole 26a and the drain-side hole 26b formed in this first interlayer insulation film forming step is determined by the exposure accuracy of the same photomask, there is hardly any variation in the length L1 of the channels 17d. In this state, the oxide semiconductor film 24 is partly exposed through the source-side holes 26a and the drain-side holes 26b.

In the first transparent electrode film forming step, the first transparent electrode film 27 and a photoresist are deposited on the gate insulation film 23, oxide semiconductor film 24, second metal film 25, and first interlayer insulation film 26, and pixel electrodes 18, source electrodes 17b, drain electrodes 17c and so on are formed as shown in FIGS. 12 and 13 by etching after exposing and developing the photoresist using a photomask. The source electrodes 17b and drain electrodes 17c are connected to the channels 17d of the oxide semiconductor film 24 respectively through the source-side holes 26a and the drain-side holes 26b of the first interlayer insulation film 26. Since the pixel electrodes 18, source electrode 17b, and drain electrodes 17c are all formed collectively in this first transparent electrode film forming step, a reduction in the production costs can favorably be achieved. After that, in the second interlayer insulation film forming step, the second interlayer insulation film 28 is deposited continuously on the first interlayer insulation film 26 and first transparent electrode film 27. In the second transparent electrode film forming step, the second transparent electrode film 29 and a photoresist are deposited on the second interlayer insulation film 28, and the common electrode 30 and so on are formed as shown in FIGS. 6 and 7 by etching after exposing and developing the photoresist using a photomask.

As described above, the array substrate (thin film transistor substrate) 11b of the present embodiment includes a source line (line) 20, a TFT (thin film transistor) 17 having a plurality of electrodes 17a, 17b, and 17c, and a line connector 31 made of light-transmitting conductive material and connected to the source line 20, and having at least a portion forming one of the plurality of electrodes 17a, 17b, and 17c.

The signal transmitted through the source line 20 is thus supplied via the line connector 31 connected to the source line 20 to one of the plurality of electrodes 17a, 17b, and 17c forming the TFT 17 that is configured by a portion of the line connector 31. Since the line connector 31 is made of light-transmitting conductive material, the amount of light transmission is increased as compared to if the line connector 31 were made of light-shielding material such as metal, as a result of which the aperture ratio is increased, which is favorable for achieving a higher resolution.

The array substrate (thin film transistor substrate) 11b further includes a pixel electrode (first transparent electrode) 18 constructed from the first transparent electrode film 27 and connected to one of the plurality of electrodes 17a, 17b and 17c of the TFT 17, and a common electrode (second transparent electrode) 30 constructed from a second transparent electrode film 29 overlapping the first transparent electrode film 27 via a second interlayer insulation film (interlayer insulation film) 28 and configured to form an electric field between itself and the pixel electrode 18. The line connector 31 is constructed from the first transparent electrode film 27. With the line connector 31 constructed from the first transparent electrode film 27 that is a light-transmitting, conductive material, the aperture ratio can thus be increased sufficiently. The pixel electrode 18 and the line connector 31 can both be formed by patterning the first transparent electrode film 27 during the production of the array substrate 11b. This enables a reduction in the production costs.

The TFT 17 includes a channel 17d constructed from an oxide semiconductor film (semiconductor film) 24. The plurality of electrodes 17a, 17b, and 17c include a source electrode 17b that is at least a portion of the line connector 31 and connected to one end of the channel 17d, and a drain electrode 17c connected to the other end of the channel 17d. The drain electrode 17c is constructed from the first transparent electrode film 27, which is one of the first and second transparent electrode films 27 and 29 that is the same one that forms the line connector 31. With the drain electrode 17c constructed from the first transparent electrode film 27 that is a light-transmitting, conductive material, the amount of light transmission is thus increased as compared to if the drain electrode were made of light-shielding material such as metal, as a result of which the aperture ratio is increased. Moreover, the drain electrodes 17c can also be formed in addition to the pixel electrodes 18 and line connectors 31 by patterning the first transparent electrode film 27 during the production of the array substrate 11b. This enables a further reduction in the production costs.

The TFT 17 includes a channel 17d constructed from the oxide semiconductor film 24. The plurality of electrodes 17a, 17b, and 17c include a source electrode 17b that is at least a portion of the line connector 31 and connected to one end of the channel 17d, and a drain electrode 17c connected to the other end of the channel 17d. A first interlayer insulation film (insulation film) 26 is arranged on the upper side of the oxide semiconductor film 24, and formed with a drain-side hole 26b and a source-side hole 26a (hole) at positions respectively overlapping the source electrode 17b and the drain electrode 17c. With the source electrode 17b and drain electrode 17c constructed from the first transparent electrode film (transparent electrode film) 27 arranged on the first interlayer insulation film 26, for example, the source electrode 17b and drain electrode 17c are thus connected to the channel 17d constructed from the oxide semiconductor film 24 respectively through the two drain-side hole 26b and source-side hole 26a formed in the first interlayer insulation film 26. Since the length L1 of the channel 17d is determined by the distance between the two drain-side hole 26b and source-side hole 26a formed in the first interlayer insulation film 26, the length L1 of the channel 17d is less likely to vary, which helps the TFT 17 exhibit its characteristics consistently.

The liquid crystal panel (display panel) 11 according to the present embodiment includes the array substrate 11b described above, and a CF substrate (counter substrate) 11a bonded to the array substrate 11b. The liquid crystal panel 11 with such a configuration is favorable for achieving a higher resolution because the aperture ratio of the array substrate 11b is made higher.

### Second Embodiment

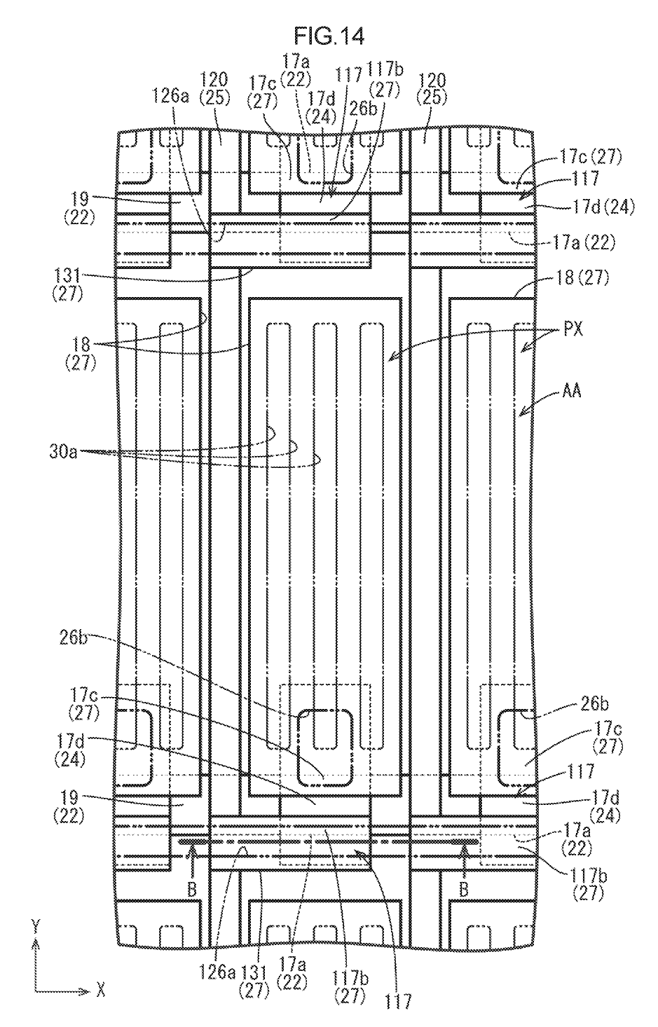

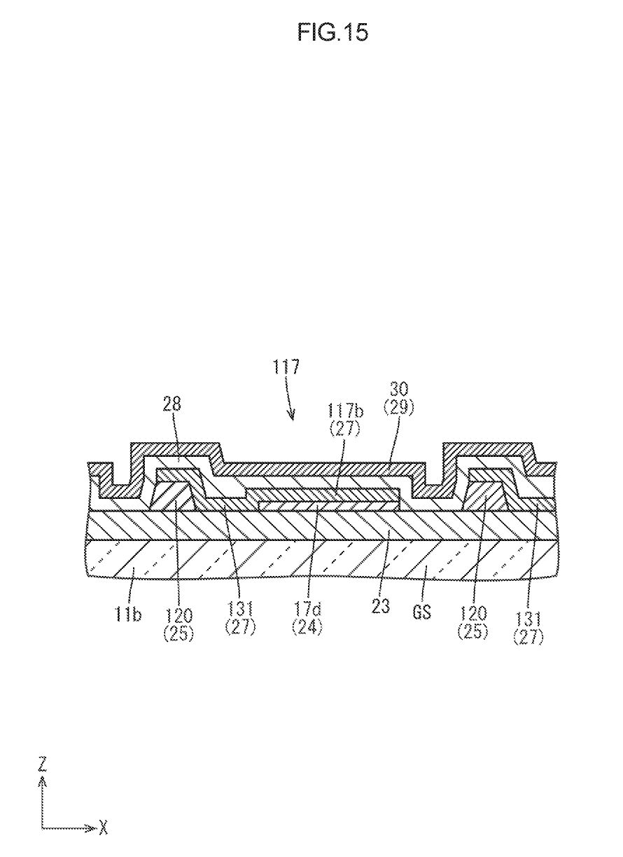

A second embodiment of the present invention will be described with reference to FIG. 14 or 15. The second embodiment illustrates an example wherein areas where source-side holes 126a are formed are changed. Repeated description of structures, effects and advantages similar to those of the first embodiment described above will be omitted.

The source-side hole 126a of a first interlayer insulation film 126 according to the present embodiment is formed in an area extending over adjacent pixels PX adjoining in the X-axis direction (direction in which a line connector 131 extends from a source line 120 toward a TFT 117), as shown in FIGS. 14 and 15. More specifically, the source-side hole 126a extends substantially over the entire length in the X-axis direction of a display area AA, in a belt-like shape crossing all the pixels PX aligned along the X-axis direction. A plurality of the belt-like source-side holes 126a are spaced at constant intervals in the Y-axis direction such that they collectively make stripes. The array pitch of the source-side holes 126a is substantially equal to the array pitch of the pixels PX in the Y-axis direction, and the number of the source-side holes 126a is equal to the number of pixels PX aligned along the Y-axis direction. If the source-side holes were formed in the first interlayer insulation film 126 discretely for the plurality of pixels PX aligned along the X-axis direction in the same number as that of the pixels PX, it would be necessary to set a constant interval between adjacent source-side holes. Such an interval need not be set if the source-side hole 126a that overlaps a source electrode 117b extends in the area over the pixels PX adjacent to each other in the X-axis direction. The array pitch of the pixels PX in the X-axis direction can thus be made smaller, which is favorable for achieving a higher resolution.

As described above, according to the present embodiment, a plurality of pixels PX having TFTs 117 are aligned along the direction in which the line connector 131 extends at least from the source line 120 toward the TFT 117. The first interlayer insulation film 126 includes a source-side hole 126a overlapping a source electrode 117b formed such as to extend in an area over pixels PX adjacent to each other in the extending direction. If the source-side holes were formed in the first interlayer insulation film discretely for the plurality of pixels PX aligned along the extending direction of the line connector 131 in the same number as that of the pixels PX, it would be necessary to set a constant interval between adjacent source-side holes. Such an interval need not be set if the source-side hole 126a that overlaps the source electrode 117b extends in the area over the pixels PX adjacent to each other in the extending direction of the line connector 131. The array pitch of the pixels PX can thus be made smaller, which is favorable for achieving a higher resolution.

### Third Embodiment

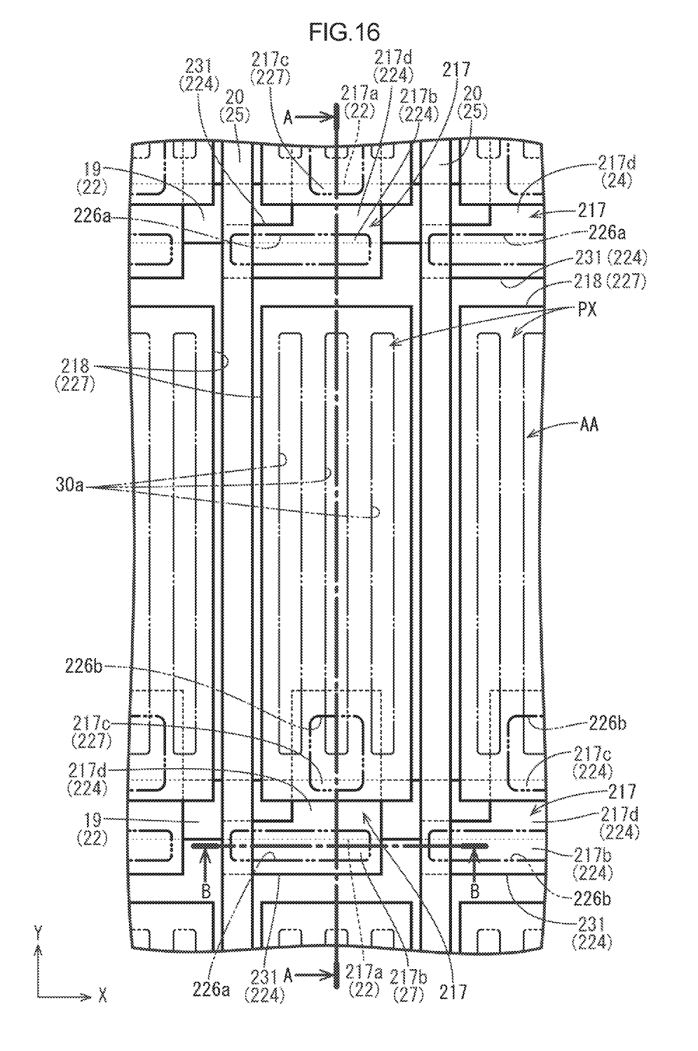

A third embodiment of the present invention will be described with reference to FIGS. 16 to 21. The third embodiment illustrates a line connector 231 having a different configuration from that of the first embodiment described above. Repeated description of structures, effects and advantages similar to those of the first embodiment described above will be omitted.

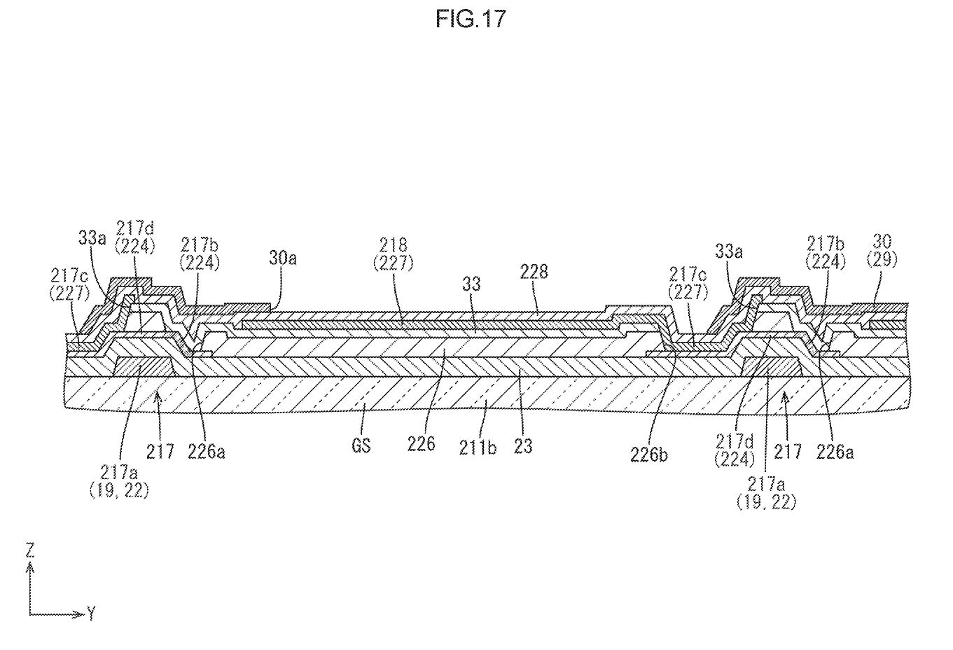

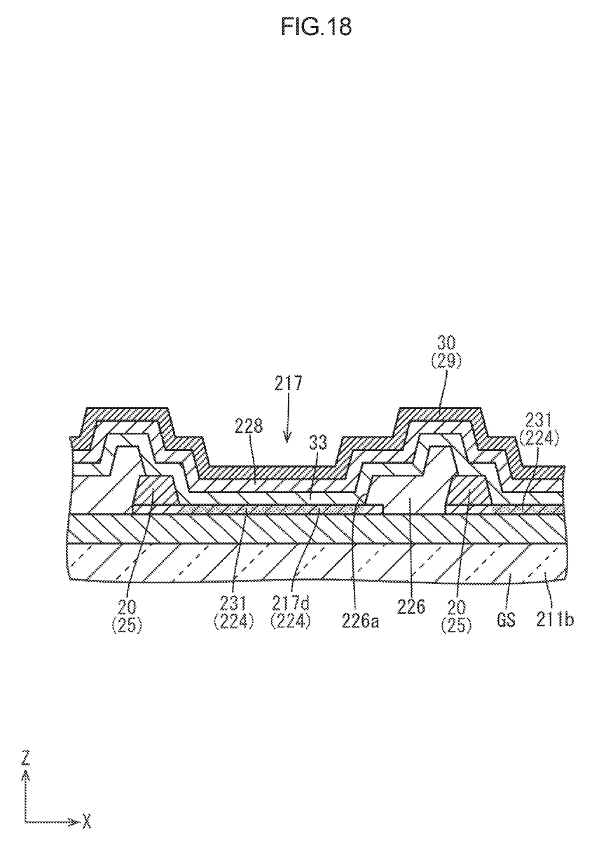

The line connector 231 including a source electrode 217b according to the present embodiment is formed by a low resistance region that is a part of an oxide semiconductor film 224 having a reduced resistance, as shown in FIGS. 16 to 18. The low resistance region of the oxide semiconductor film 224 is a region that functions as a conductor having a certain resistivity (e.g., a resistivity that is about 1/10000000000 to 1/100 of the resistivity of a channel 217d, which is not a low resistance region). In FIGS. 17 and 18, the line connectors 231 (low resistance regions of the oxide semiconductor film 224) are illustrated with shading. The oxide semiconductor film 224 including the low resistance regions are made of light-transmitting conductive material that is substantially transparent. Therefore, the aperture ratio of pixels PX can be increased sufficiently by forming the line connectors 231 by a part of the oxide semiconductor film 224 (low resistance regions). The channels 217d and the line connectors 231 including the source electrodes 217b can both be formed by patterning the oxide semiconductor film 224 during the production of the array substrate 211b, so that the production costs can be reduced.

Various films stacked on the array substrate 211b according to the present embodiment further include a third interlayer insulation film 33 interposed between a first interlayer insulation film 226 and a first transparent electrode film 227, as shown in FIG. 17. The third interlayer insulation film 33 is made of inorganic material such as silicon nitride, for example, and should preferably have a film thickness of about 100 nm, for example. The line connectors 231 substantially entirely overlap source-side holes 226a in the first interlayer insulation film 226 as shown in FIGS. 17 and 18. The third interlayer insulation film 33 stacked on the upper side of the first interlayer insulation film 226 thus directly contacts exposed portions of the oxide semiconductor film 224 exposed through the source-side holes 226a in the first interlayer insulation film 226. The third interlayer insulation film 33 and the second interlayer insulation film 228 are made of the same material and the third interlayer insulating film 33 contains hydrogen. Therefore, the hydrogen contained in the third interlayer insulation film 33 diffuses to the exposed portions of the oxide semiconductor film 224 through the source-side holes 226a in the first interlayer insulation film 226 and makes the resistance of the exposed portions lower. The exposed portions of the oxide semiconductor film 224 thus become substantially entirely low resistance regions and form the line connectors 231. The third interlayer insulation film 33 has third drain-side holes 33a at positions overlapping the drain-side holes 226b in order to connect the pixel electrodes 218 constructed from the first transparent electrode film 227 to the drain electrodes 217c. In the production process of the array substrate 211b, after forming the third interlayer insulation film 33, a photoresist is deposited on the third interlayer insulation film 33, and the third drain-side holes 33a are formed by etching after exposing and developing the photoresist using a photomask.

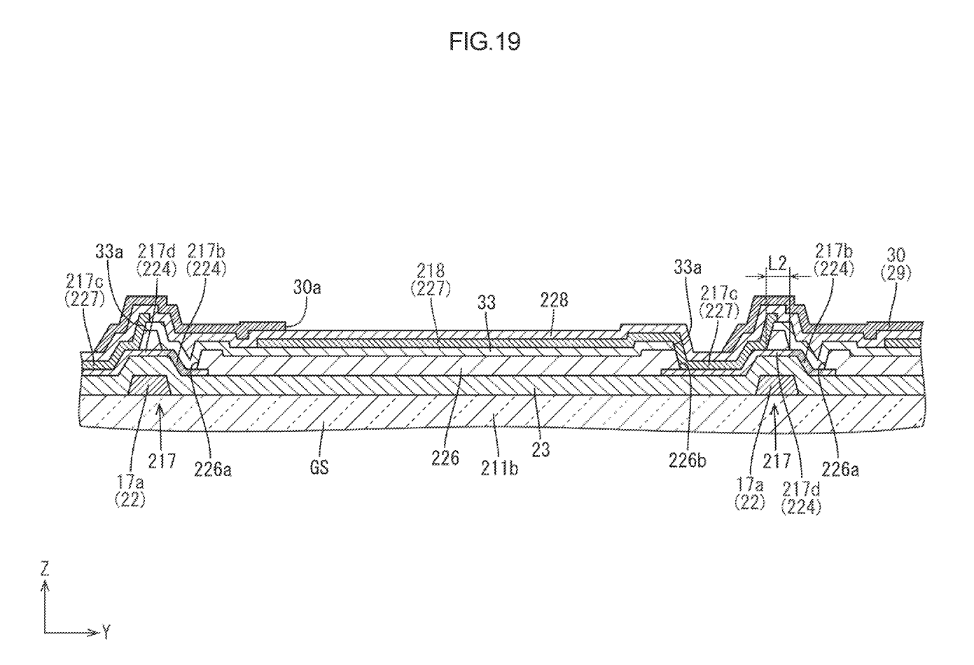

On the other hand, drain electrodes 217c are constructed from the same first transparent electrode film 227 that forms the pixel electrodes 218 as shown in FIG. 17 similarly to the previously described first embodiment. The line connectors 231 including the source electrodes 217b include low resistance regions of the oxide semiconductor film 224 as described above but not the first transparent electrode film 227. Therefore, the distance that needs to be secured between a drain electrode 217c and a source electrode 217b can be set shorter as compared to the configuration in which the drain electrodes 17c and source electrodes 17b are constructed from the first transparent electrode film 27 as described in the first embodiment section (see FIGS. 6 and 7). More specifically, as shown in FIG. 19, the length L2 of the channel 217d can be made shorter than the length L1 of the channel 17d described in the first embodiment. Thus, the characteristics of the TFT 217 can be improved. Moreover, since the length of the channel 217d is determined by the distance between the two holes 226a and 226b formed in the first interlayer insulation film 226 similarly to the first embodiment described above, the length of the channel 217d is less likely to vary, which helps the TFT 217 exhibit its characteristics consistently.

As described above, according to the present embodiment, the TFT 217 includes a channel 217d constructed from an oxide semiconductor film 224. The plurality of electrodes 217a, 217b, and 217c include a source electrode 217b that is at least a portion of the line connector 231 and connected to one end of the channel 217d, and a drain electrode 217c connected to the other end of the channel 217d. The line connectors 231 are formed by low resistance regions that are parts of the oxide semiconductor film 224 having a reduced resistance. With the line connectors 231 formed by low resistance regions that are parts of the oxide semiconductor film 224 made of light-transmitting conductive material and having a reduced resistance, the aperture ratio can thus be increased sufficiently. The channels 217d and the line connectors 231 can both be formed by patterning the oxide semiconductor film 224 during the production of the array substrate 211b. This enables a reduction in the production costs.

The array substrate 211b further includes pixel electrodes 218 constructed from the first transparent electrode film 227 and connected to the drain electrodes 217c of the TFTs 217, and the common electrode 230 constructed from the second transparent electrode film 229 overlapping the first transparent electrode film 227 via a second interlayer insulation film 228 and configured to form a capacitor or an electric field between itself and the pixel electrode 218. The drain electrode 217c is constructed from the first transparent electrode film 227. With the drain electrode 217c constructed from the first transparent electrode film 227 that is a light-transmitting, conductive material, the amount of light transmission is thus increased as compared to if the drain electrode were made of light-shielding material such as metal, as a result of which the aperture ratio is increased. Moreover, the pixel electrodes 218 or common electrode 230 and the drain electrodes 217c can be formed by patterning the first transparent electrode film 227 during the production of the array substrate 211b. This enables a further reduction in the production costs. Moreover, since the drain electrodes 217c are constructed from the first transparent electrode film 227 while the source electrodes 217b are formed by low resistance regions of the oxide semiconductor film 224, the distance that needs to be secured between a drain electrode 217c and a source electrode 217b can be set shorter as compared to when the drain electrodes and source electrodes were constructed from the same transparent electrode film. The channels 217d can therefore be made shorter, so that the characteristics of the TFTs 217 can be improved.

### Fourth Embodiment

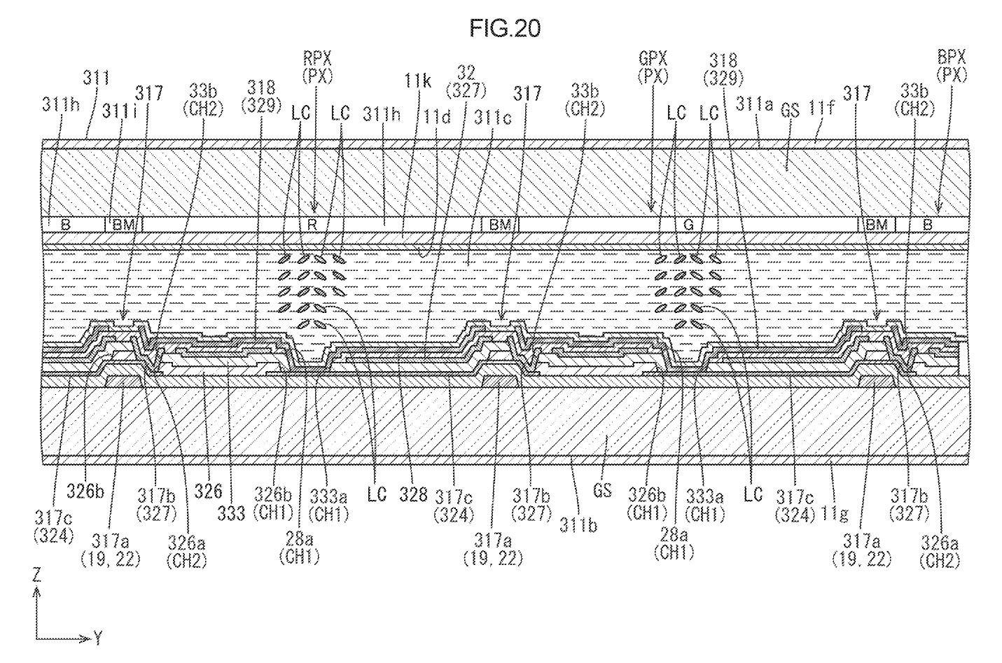

A fourth embodiment of the present invention will be described with reference to FIGS. 20 to 29. The fourth embodiment illustrates a liquid crystal panel 311 with its mode changed from that of the previously described first embodiment to VA (Vertical Alignment) mode. Repeated description of structures, effects and advantages similar to those of the first embodiment described above will be omitted.

For the liquid crystal panel 311 according to the present embodiment, as shown in FIG. 20, a negative nematic liquid crystal material is used for example as the liquid crystal material that forms the liquid crystal layer 311c. In an initial state where no electric field is applied between both substrates 311a and 311b (OFF state), the liquid crystal molecules LC are oriented substantially perpendicular to respective orientation films 311d and 311e on the surfaces of both substrates 311a and 311b. Therefore, the liquid crystal panel 311 according to the present embodiment operates in a mode known as VA mode. FIG. 20 schematically illustrates the orientation of liquid crystal molecules LC contained in the liquid crystal layer 311c in the initial state.

Since the liquid crystal panel 311 according to the present embodiment operates in VA mode as mentioned above, a CF substrate 311a opposite an array substrate 311b has a counter electrode 11k as shown in FIG. 20. The counter electrode 11k is stacked on the surfaces of the color filters 311h and light shields 311i of the CF substrate 311a, and formed continuously substantially over the entire area of an inner face of the CF substrate 311a. The counter electrode 11k is made of transparent electrode material such as ITO (indium tin oxide), for example, and should preferably have a film thickness of about 100 nm, for example. This counter electrode 11k has a reference potential that is always kept at a constant level. Therefore, as each TFT 317 is driven and voltage is applied to each pixel electrode 318 connected to each TFT 317, there is created a potential difference between the counter electrode 11k and each pixel electrode 318. The orientation of the liquid crystal molecules LC contained in the liquid crystal layer 311c changes in accordance with the potential difference between the counter electrode 11k and each pixel electrode 318, which varies the polarization state of passing light. The amount of light transmission is thus controlled individually for each of the pixels PX of the liquid crystal panel 311 such that a predetermined color image is displayed.

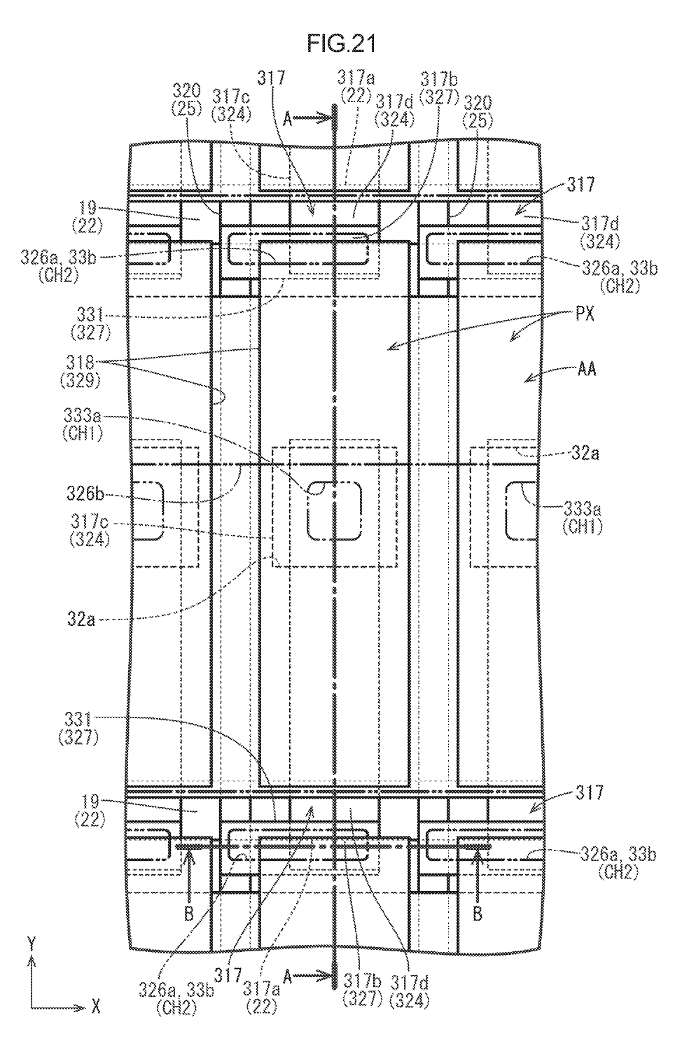

Of the various films deposited on the array substrate 311b, a first transparent electrode film 327 forms auxiliary capacitance electrodes 32 overlapping pixel electrodes 318, while a second transparent electrode film 329 forms the pixel electrodes 318, respectively, as shown in FIGS. 20 and 21. Namely, in the present embodiment, the pixel electrodes 318 are formed by the second transparent electrode film 329, which is on the upper side of the first transparent electrode film 327. The auxiliary capacitance electrodes 32 form a capacitor between themselves and the pixel electrodes 318 to keep the potential of the charged pixel electrodes 318 for a predetermined period. The auxiliary capacitance electrode 32 extends substantially over the entire length in the X-axis direction of a display area AA (extending direction of the line connector 331), in a belt-like shape crossing all the pixels PX aligned along the X-axis direction. A plurality of the belt-like auxiliary capacitance electrodes 32 are spaced at constant intervals in the Y-axis direction (extending direction of the source lines 320) such that they collectively make stripes. The array pitch of the auxiliary capacitance electrodes 32 is substantially equal to the array pitch of the pixels PX in the Y-axis direction, and the number of the auxiliary capacitance electrodes 32 is equal to the number of pixels PX aligned along the Y-axis direction. A plurality of island-shaped holes 32a are formed in the auxiliary capacitance electrodes 32 at positions overlapping drain-side contact holes CH1 of the pixels PX to be described later.

Various films stacked on the array substrate 311b according to the present embodiment further include a third interlayer insulation film 333 interposed between a first interlayer insulation film 326 and the first transparent electrode film 327, as shown in FIG. 20, similarly to the previously described third embodiment. The third interlayer insulation film 333 is made of inorganic material such as silicon nitride, for example, and should preferably have a film thickness of about 200 nm, for example. Namely, the third interlayer insulation film 333 is made of the same material as that of the second interlayer insulation film 328 and contains hydrogen. The first interlayer insulation film 326 should preferably have a film thickness of about 200 nm, for example, i.e., equal to the film thickness of the third interlayer insulation film 333 (but thinner than the film thickness of the second interlayer insulation film 328).

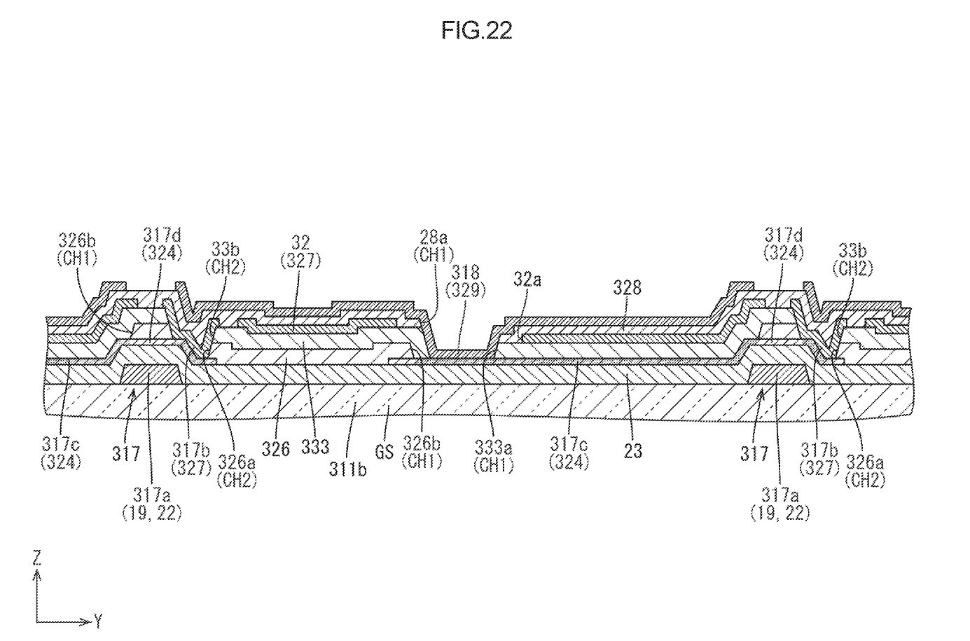

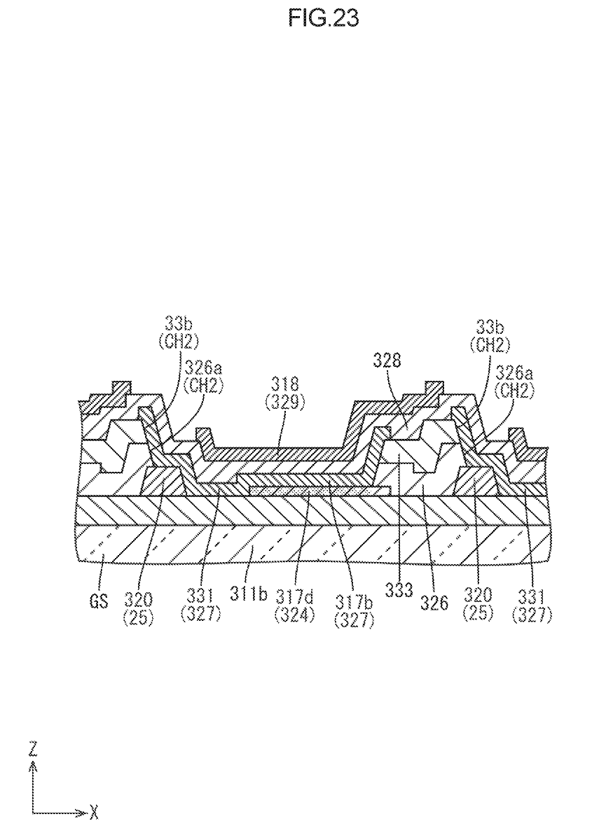

A drain electrode 317c according to the present embodiment is arranged such as to extend straight along the Y-axis direction from one end of a channel 317d opposite from the source electrode 317b side to near a central position in the X-axis and Y-axis directions of the pixel PX, as shown in FIGS. 21 and 22. The end of the drain electrode 317c opposite from the channel 317d makes a connecting point connected to the pixel electrode 318. The drain electrode 317c is formed by a low resistance region that is a part of the oxide semiconductor film 324 having a reduced resistance. The low resistance region of the oxide semiconductor film 324 is a region that functions as a conductor having a certain resistivity (e.g., a resistivity that is about 1/10000000000 to 1/100 of the resistivity of the channel 317d, which is not a low resistance region). In FIGS. 22 and 23, the low resistance regions of the oxide semiconductor film 324 (including the drain electrodes 317c) are illustrated with shading. The oxide semiconductor film 324 including the low resistance regions is made of light-transmitting conductive material that is substantially transparent. Therefore, the aperture ratio of pixels PX can be increased sufficiently by forming the drain electrodes 317c by a part of the oxide semiconductor film 324 (low resistance regions). The channels 317d and drain electrodes 317c can both be formed by patterning the oxide semiconductor film 324 during the production of the array substrate 311b, so that the production costs can be reduced.

As shown in FIG. 22, a drain-side hole 326b in the first interlayer insulation film 326 arranged on the upper side of the oxide semiconductor film 324 is formed in an area along the Y-axis direction that extends from one end of the channel 317d opposite from the source electrode 317b side to near a central position in the X-axis and Y-axis directions of the pixel PX. Namely, the drain-side hole 326b overlaps the drain electrode 317c substantially over the entire length along the Y-axis direction. Similarly to the auxiliary capacitance electrode 32, the drain-side hole 326b extends substantially over the entire length in the X-axis direction of a display area AA, in a belt-like shape crossing all the pixels PX aligned along the X-axis direction. A plurality of the belt-like drain-side holes 326b are spaced at constant intervals in the Y-axis direction such that they collectively make stripes. The array pitch of the drain-side holes 326b is substantially equal to the array pitch of the pixels PX in the Y-axis direction, and the number of the drain-side holes 326b is equal to the number of pixels PX aligned along the Y-axis direction. The third interlayer insulation film 333 stacked on the upper side of the first interlayer insulation film 326 thus directly contacts exposed portions of the oxide semiconductor film 324 exposed through the drain-side holes 326b in the first interlayer insulation film 326. The third interlayer insulation film 333 is made of silicon nitride as mentioned above and contains hydrogen. Therefore, the hydrogen contained in the third interlayer insulation film 333 diffuses to the exposed portions of the oxide semiconductor film 324 through the drain-side holes 326b in the first interlayer insulation film 326 and makes the resistance of the exposed portions lower. The exposed portions of the oxide semiconductor film 324 thus become substantially entirely low resistance regions and form the drain electrodes 317c. The exposed portions of the oxide semiconductor film 324 exposed through source-side holes 326a of the first interlayer insulation film 326 similarly have a reduced resistance due to the hydrogen introduced from the third interlayer insulation film 333.

On the other hand, line connectors 331 including source electrodes 317b are constructed from the same first transparent electrode film (second transparent electrode film) 327 that forms the auxiliary capacitance electrodes 32 as shown in FIGS. 22 and 23. Since the drain electrodes 317c are formed by low resistance regions of the oxide semiconductor film 324 while the source electrodes 317b are constructed from the first transparent electrode film 327, the distance that needs to be secured between a drain electrode 317c and a source electrode 317b can be set shorter as compared to when the drain electrodes and source electrodes were constructed from the same transparent electrode film. The channels 317d can therefore be made shorter, so that the characteristics of the TFTs 317 can be improved. Moreover, since the line connectors 331 are constructed from the same first transparent electrode film 327 that forms the auxiliary capacitance electrode 32, the configuration wherein the pixel electrodes 318 constructed from the second transparent electrode film 329 overlap the line connectors 331 can be adopted. More specifically, as shown in FIGS. 21 and 22, the pixel electrode 318 is arranged such that one end opposite from the channel 317d side in the Y-axis direction overlaps parts of the source electrode 317b and gate electrode 317a of a pixel PX adjacent to each other above in the Y-axis direction in FIG. 21. This way, the pixel electrode 318 can be formed in a wider area, so that the aperture ratio can be increased.

As described above, the pixel electrodes 318 are constructed from the second transparent electrode film 329, while the third interlayer insulation film 333 is formed on the upper side of the first interlayer insulation film 326. Therefore, the third interlayer insulation film 333 is provided with third drain-side holes 333a at positions overlapping the drain-side holes 326b so as to connect the pixel electrodes 318 with the drain electrodes 317c as shown in FIGS. 22 and 23. The third drain-side hole 333a is positioned near a central position in the X-axis and Y-axis directions of the pixel PX, overlapping one end of the drain electrode 317c opposite from the channel 317d side in the Y-axis direction. The third drain-side hole 333a is quadrilateral as viewed in plan, each side having a length shorter than the width (dimension in the X-axis direction) of the drain electrode 317c. The second interlayer insulation film 328 disposed on the upper side of the third interlayer insulation film 333 also has second drain-side holes 28a at positions overlapping the third drain-side holes 333a mentioned above, over substantially the same area. The overlapping regions of the drain-side hole 326b, second drain-side hole 28a, and third drain-side hole 333a form a drain-side contact hole CH1 for connecting the pixel electrode 318 with the drain electrode 317c. Therefore, it can be said that the area where drain-side contact hole CH1 is formed is defined by the areas where the second drain-side hole 28a and third drain-side hole 333a are formed. In the third interlayer insulation film 333, at positions overlapping the source-side holes 326a of the first interlayer insulation film 326, third source-side holes 33b are formed substantially over the same area as the source-side holes 326a, as shown in FIGS. 21 and 23. These source-side holes 326a and third source-side holes 33b form source-side contact holes CH2 for connecting line connectors 331 with the channels 317d and source lines 320. In FIG. 21, the areas where the source-side hole 326a and drain-side hole 326b are formed are indicated by relatively thick two-dot chain lines, while the area where the third drain-side hole 333a is formed is indicated by relatively thin one-dot chain lines. The second drain-side hole 28a is not shown.

As the drain-side contact holes CH1 are formed through each of the interlayer insulation films 333, 326, and 328 as described above, there is formed a recess near the central position in the X-axis and Y-axis directions of each pixel PX on the surface of the array substrate 311b as shown in FIG. 20. This recess can orient the liquid crystal molecules LC contained in the liquid crystal layer 311c radially in the initial state. As compared to if an additional recess or protrusion were provided separately from the drain-side contact hole CH1 for controlling the orientation of liquid crystal molecules LC, the array pitch of the pixels PX can be made shorter, since the space for providing such a recess or protrusion is not necessary, which is favorable for achieving an even higher resolution.

The liquid crystal panel 311 according to the present embodiment is configured as described above. Next, the method of producing the panel, in particular, the array substrate 311b, will be described. The production process of the array substrate 311b according to the present embodiment further includes a third interlayer insulation film forming step wherein the third interlayer insulation film 333 is deposited and patterned, in addition to the steps described in the first embodiment. The third interlayer insulation film forming step is performed between the second metal film forming step and the first transparent electrode film forming step.

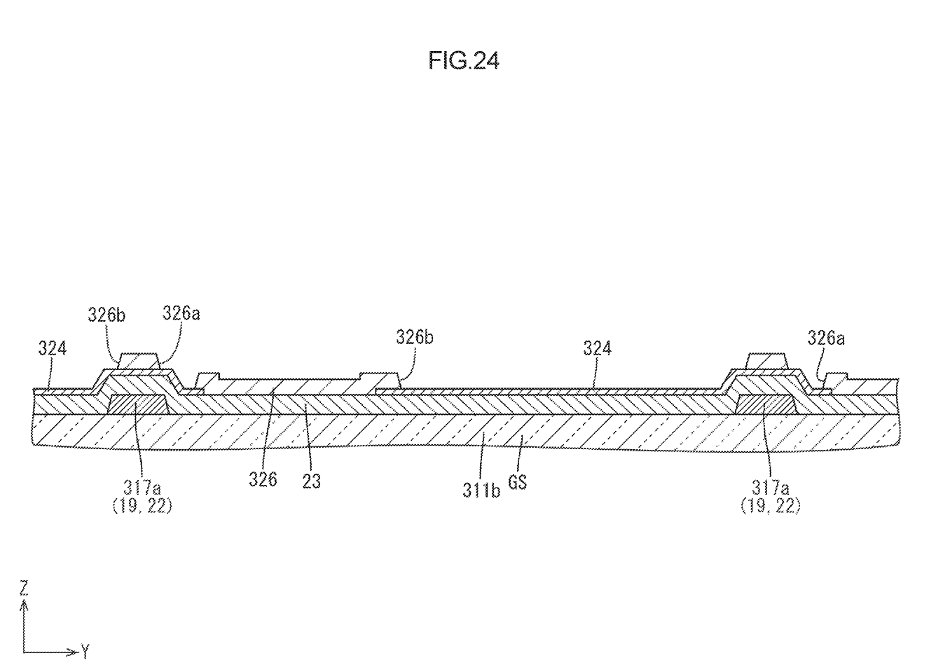

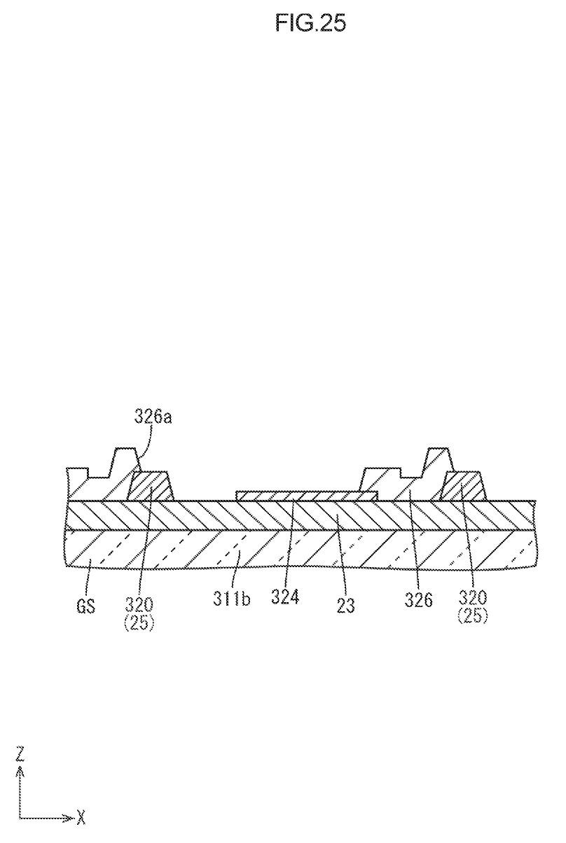

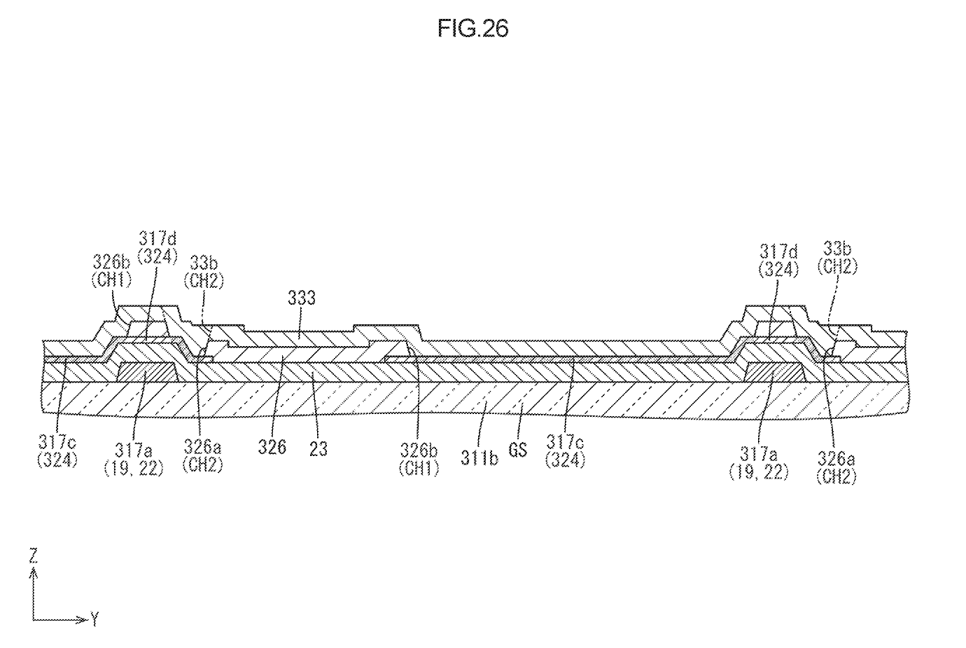

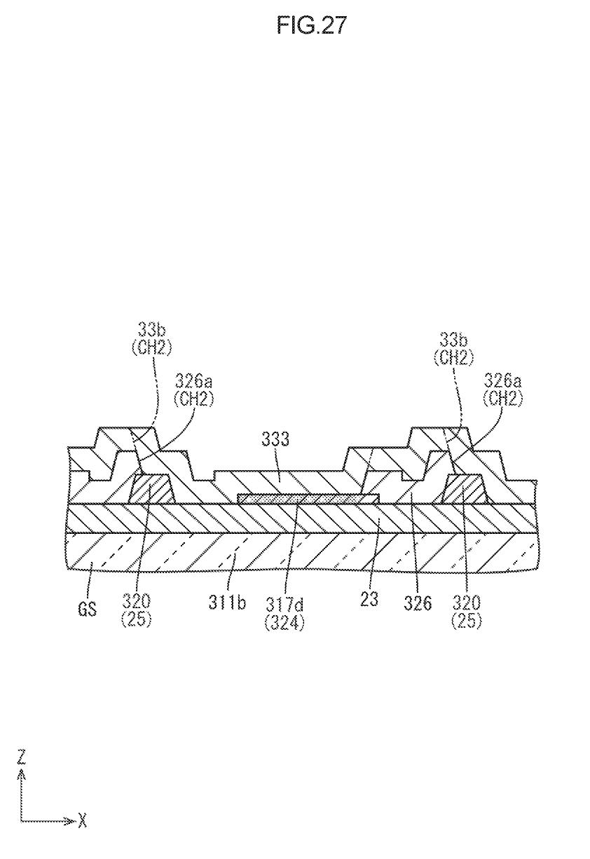

In the first interlayer insulation film forming step included in the production method of the array substrate 311b, the deposited first interlayer insulation film 326 is patterned to form the source-side holes 326a and drain-side holes 326b as shown in FIGS. 24 and 25. In this state, the oxide semiconductor film 324 is partly exposed through holes 326a and 326b in portions overlapping the source-side holes 326a and the drain-side holes 326b. In the successive third interlayer insulation film forming step, the third interlayer insulation film 333 is deposited on the oxide semiconductor film 324 and first interlayer insulation film 326 as shown in FIGS. 26 and 27. The deposited third interlayer insulation film 333 directly contacts exposed portions of the oxide semiconductor film 324 through the source-side holes 326a and drain-side holes 326b in the first interlayer insulation film 326. Since the third interlayer insulation film 333 contains hydrogen in its material, the hydrogen diffuses into the exposed portions of the oxide semiconductor film 324 through the source-side holes 326a and drain-side holes 326b and makes the resistance of the exposed portions lower. The exposed portions of the oxide semiconductor film 324 thus become substantially entirely low resistance regions and form the drain electrodes 317c and so on. After that, a photoresist is deposited on the third interlayer insulation film 333, and the third source-side holes 33b are formed by etching after exposing and developing the photoresist using a photomask (see two-dot chain lines in FIGS. 26 and 27).

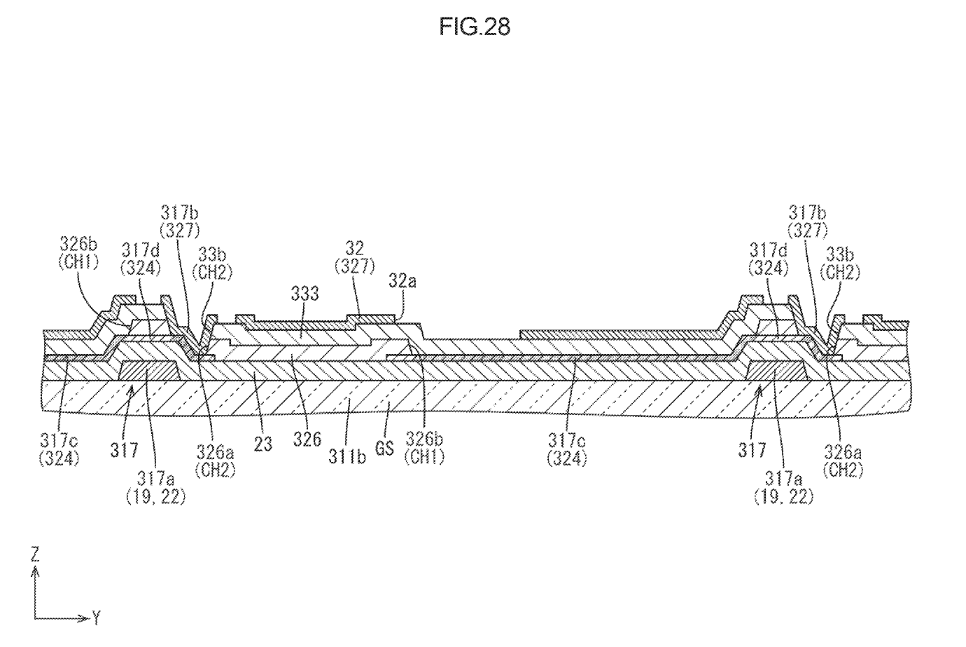

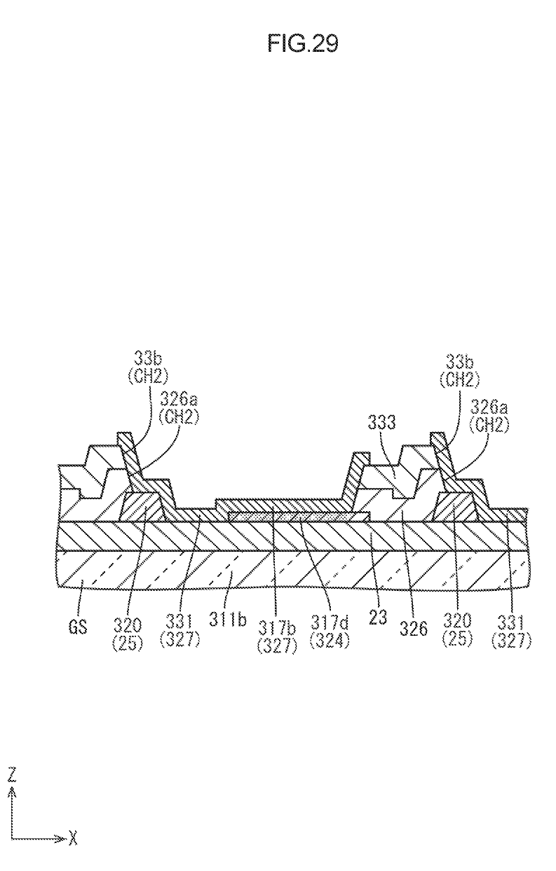

In the first transparent electrode film forming step, the first transparent electrode film 327 is deposited and patterned. The line connectors 331 constructed from the first transparent electrode film 327 are then connected to the low resistance regions of the oxide semiconductor film 324 on the source electrode 317b side through the source-side contact holes CH2 (source-side holes 326a and third source-side holes 33b), as shown in FIGS. 28 and 29. Openings 32a are formed in the auxiliary capacitance electrodes 32 around the region where the drain-side contact holes CH1 are formed. In the second interlayer insulation film forming step, the second interlayer insulation film 328 of the same material as the third interlayer insulation film 33 is deposited. The second interlayer insulation film 328 and third interlayer insulation film 33 are together patterned, to form the second drain-side holes 28a and the third drain-side holes 333a. The drain-side contact holes CH1 are thus formed. In the second transparent electrode film forming step, the second transparent electrode film 329 is deposited and patterned. The pixel electrodes 318 constructed from the second transparent electrode film 329 are then connected to the drain electrodes 317c that are the drain-side low resistance regions of the oxide semiconductor film 324 through the drain-side contact holes CH1 (drain-side holes 326b, third drain-side holes 333a, and second drain-side holes 28a), as shown in FIGS. 22 and 23.

As described above, according to the present embodiment, the array substrate 311b includes a pixel electrode (first transparent electrode) 318 constructed from the second transparent electrode film (first transparent electrode film) 329 and connected to one of the plurality of electrodes 317a, 317b and 317c of the TFT 317, and an auxiliary capacitance electrode (second transparent electrode) 32 constructed from the first transparent electrode film (second transparent electrode film) 327 overlapping the second transparent electrode film 29 via the second interlayer insulation film 328 and configured to form a capacitor between itself and the pixel electrode 318. The line connector 331 is constructed from the first transparent electrode film 327. With the line connector 331 constructed from the first transparent electrode film 327 that is a light-transmitting, conductive material, the aperture ratio can thus be increased sufficiently. The auxiliary capacitance electrodes 32 and the line connectors 331 can both be formed by patterning the first transparent electrode film 327 during the production of the array substrate 311b. This enables a reduction in the production costs.

The TFT 317 includes a channel 317d constructed from an oxide semiconductor film 324. The plurality of electrodes 317a, 317b, and 317c include a source electrode 317b that is at least a portion of the line connector 331 and connected to one end of the channel 317d, and a drain electrode 317c connected to the other end of the channel 317d. The drain electrode 317c is formed by a low resistance region that is a part of the oxide semiconductor film 324 having a reduced resistance. With the drain electrode 317c formed by a low resistance region that is a part of the oxide semiconductor film 324 made of light-transmitting conductive material and having a reduced resistance, the amount of light transmission is thus increased as compared to if the drain electrode were made of light-shielding material such as metal, as a result of which the aperture ratio can be further increased. The drain electrodes 317c can also be formed in addition to the channels 317d by patterning the oxide semiconductor film 324 during the production of the array substrate 311b. This enables a further reduction in the production costs. Moreover, since the drain electrodes 317c are formed by low resistance regions of the oxide semiconductor film 324 while the source electrodes 317b are constructed from the first transparent electrode film 327, the distance that needs to be secured between a drain electrode 317c and a source electrode 317b can be set shorter as compared to when the drain electrodes and source electrodes were constructed from the same transparent electrode film. The channels 317d can therefore be made shorter, so that the characteristics of the TFTs 317 can be improved.

The first transparent electrode is a pixel electrode 318 partly overlapping the line connector 331, while the second transparent electrode is an auxiliary capacitance electrode 32 that forms a capacitance between itself and the pixel electrode 318 to keep a potential of the charged pixel electrode 318. The line connector 331 is constructed from the first transparent electrode film 327. With the line connector 331 constructed from the same first transparent electrode film 327 that forms the auxiliary capacitance electrode 32, a configuration can be adopted wherein the pixel electrode 318 constructed from the second transparent electrode film 329 overlaps the line connector 331. This way, the pixel electrode 318 can be formed in a wider area, so that the aperture ratio can be increased.

### Fifth Embodiment

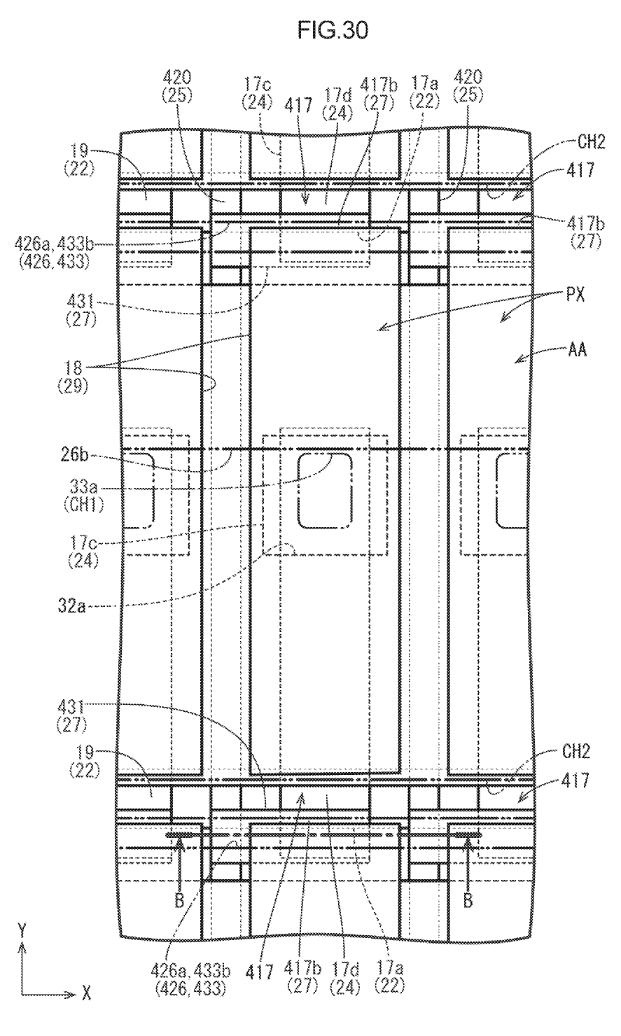

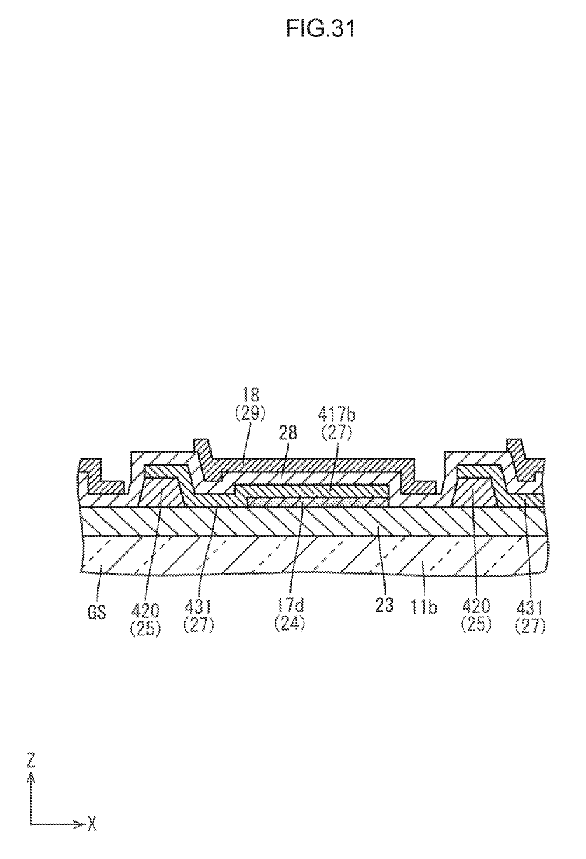

A fifth embodiment of the present invention will be described with reference to FIG. 30 or 31. The fifth embodiment illustrates an example wherein the areas where source-side holes 426a and third source-side holes 433b are formed are changed from those of the fourth embodiment described above. Repeated description of structures, effects and advantages similar to those of the fourth embodiment described above will be omitted.

The source-side hole 426a and third source-side hole 433b of a first interlayer insulation film 426 and a third interlayer insulation film 433 according to the present embodiment are formed in an area extending over adjacent pixels PX adjoining in the X-axis direction (direction in which a line connector 431 extends from a source line 420 toward a TFT 417), as shown in FIGS. 30 and 31. More specifically, the source-side hole 426a and third source-side hole 433b extend substantially over the entire length in the X-axis direction of a display area AA, in a belt-like shape crossing all the pixels PX aligned along the X-axis direction. A plurality of the belt-like source-side holes 426a and third source-side holes 433b are spaced at constant intervals in the Y-axis direction such that they collectively make stripes. The array pitch of the source-side holes 426a is substantially equal to the array pitch of the pixels PX in the Y-axis direction, and the number of the source-side holes 426a is equal to the number of pixels PX aligned along the Y-axis direction. If the source-side holes and third source-side holes were formed in the first interlayer insulation film 426 and the third interlayer insulation film 433 discretely for the plurality of pixels PX aligned along the X-axis direction in the same number as that of the pixels PX, it would be necessary to set a constant interval between adjacent source-side holes and third source-side holes. Such an interval need not be set if the source-side holes 426a and third source-side holes 433b that overlap source electrodes 417b extend in the area over the pixels PX adjacent to each other in the X-axis direction. The array pitch of the pixels PX in the X-axis direction can thus be made smaller, which is favorable for achieving a higher resolution.

### Sixth Embodiment

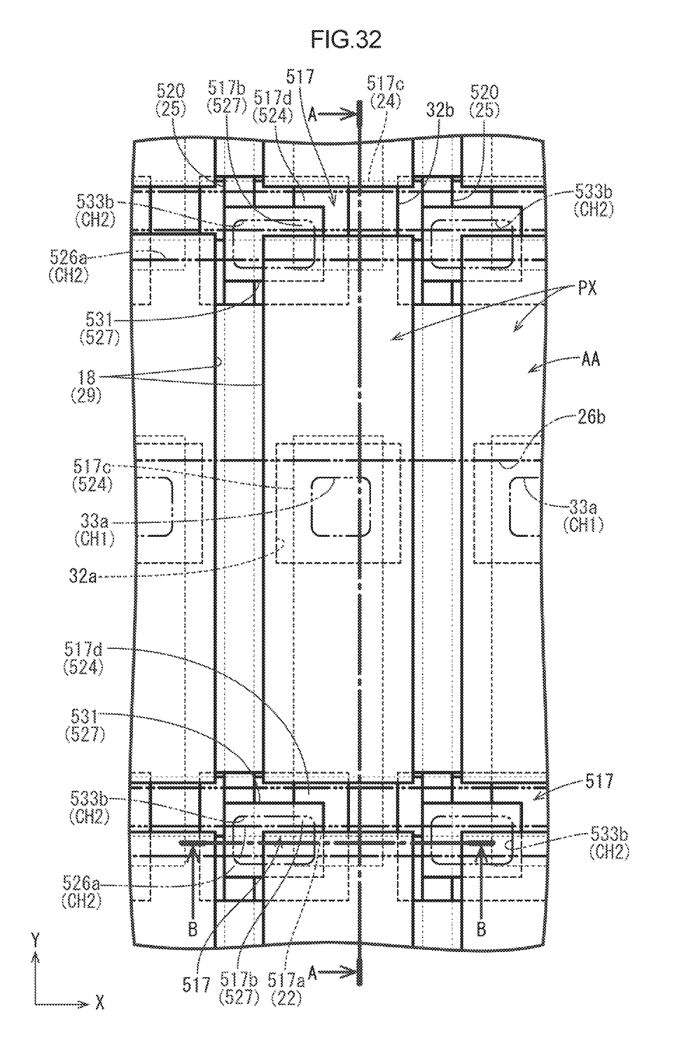

A sixth embodiment of the present invention will be described with reference to FIGS. 32 to 34. A sixth embodiment illustrates an example wherein the areas where line connectors 531, third source-side holes 533b, and auxiliary capacitance electrodes 532 are formed are changed from those of the fifth embodiment described above. Repeated description of structures, effects and advantages similar to those of the fifth embodiment described above will be omitted.

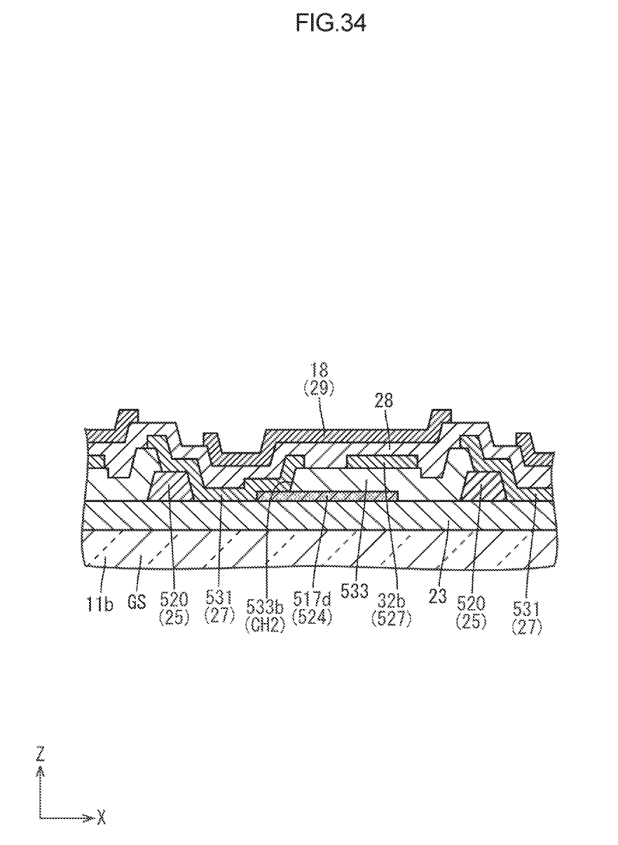

The line connectors 531 according to the present embodiment are formed in areas extending from parts of the channels 517d, more specifically parts on the source line 520 side in the X-axis direction of the channel 517d, to source lines 520 as shown in FIGS. 32 and 34. The third source-side holes 533b in a third interlayer insulation film 533 to form source-side contact holes CH2 are formed in areas that are substantially the same as those of the line connectors 531, i.e., areas extending from ends of the channels 517d on the source line 520 side in the X-axis direction of the channel 517d to the source lines 520. Source-side holes 526a in a first interlayer insulation film 526 are formed in the same areas as those of the fifth embodiment described above, partly overlapping the third source-side holes 533b to form the source-side contact holes CH2.

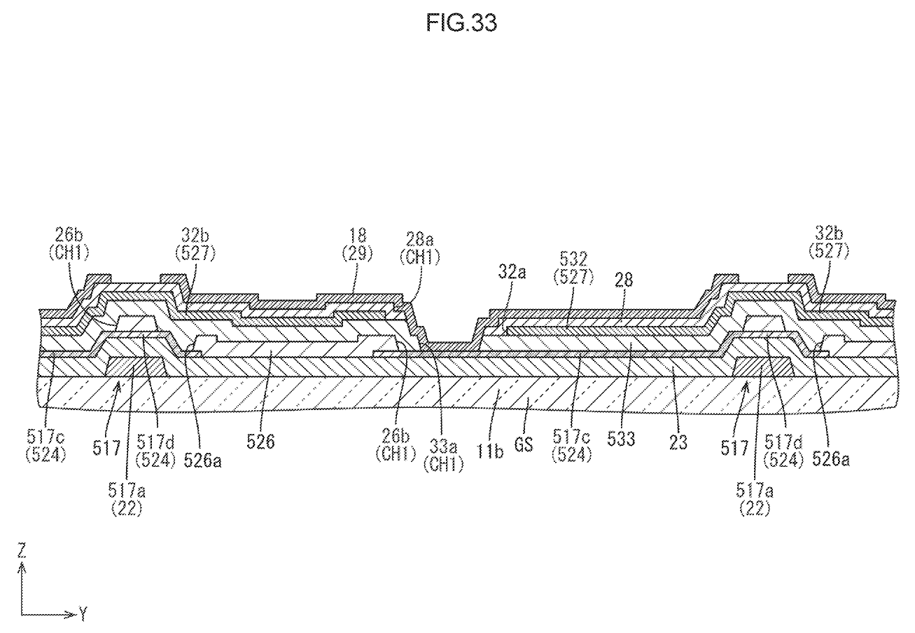

The line connectors 531 are constructed from the same first transparent electrode film 527 that forms the auxiliary capacitance electrodes 532. In the present embodiment, the areas where the auxiliary capacitance electrodes 532 are formed are extended such that they are wider than those of the foregoing fifth embodiment, so as to overlap portions of the channels 517d that do not overlap the line connectors 531 (portions opposite from the source line 520 side in the X-axis direction) as shown in FIGS. 32 and 33, utilizing the fact that the line connectors 531 are formed in areas that overlap parts of the channels 517d as described above. The auxiliary capacitance electrodes 532 that are adjacent to each other in the Y-axis direction are connected by the extended portions 32b. Therefore, the auxiliary capacitance electrodes 532 have a reduced electrical resistance. Although the auxiliary capacitance electrodes 532 and line connectors 531 are both constructed from the same first transparent electrode film 527, they are physically separated from each other to prevent short-circuiting.

As described above, according to the present embodiment, the TFT 517 includes a channel 517d constructed from an oxide semiconductor film 524. The plurality of electrodes 517a, 517b, and 517c include a source electrode 517b that is at least a portion of the line connector 531 and connected to one end of the channel 517d, and a drain electrode 517c connected to the other end of the channel 517d. A first interlayer insulation film (insulation film) 526 is arranged on the upper side of the oxide semiconductor film 524, and is formed with a drain-side hole 526b and a source-side hole 526a (hole) at positions respectively overlapping the source electrode 517b and the drain electrode 517c. With the source electrode 517b and drain electrode 517c formed by low resistance regions that are parts of the oxide semiconductor film 524 having a reduced resistance, the resistance of the oxide semiconductor film 524 may be reduced through the two drain-side hole 526b and source-side hole 526a formed in the first interlayer insulation film 526, which allows for formation of a source electrode 517b and a drain electrode 517c connected to the channel 517d. Since the length of the channel 517d is determined by the distance between the two drain-side hole 526b and source-side hole 526a formed in the first interlayer insulation film 526, the length of the channel 517d is less likely to vary, which helps the TFT 517 exhibit its characteristics consistently.

### Seventh Embodiment

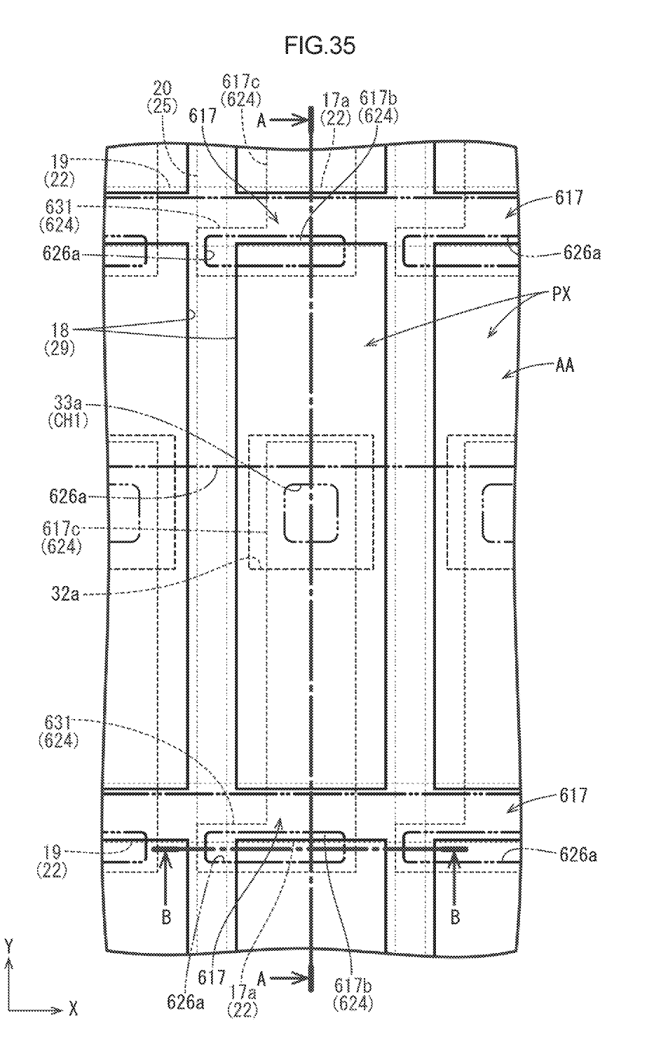

A seventh embodiment of the present invention will be described with reference to FIGS. 35 to 37. The seventh embodiment illustrates a line connector 631 having a different configuration from that of the fourth embodiment described above. Repeated description of structures, effects and advantages similar to those of the fourth embodiment described above will be omitted.

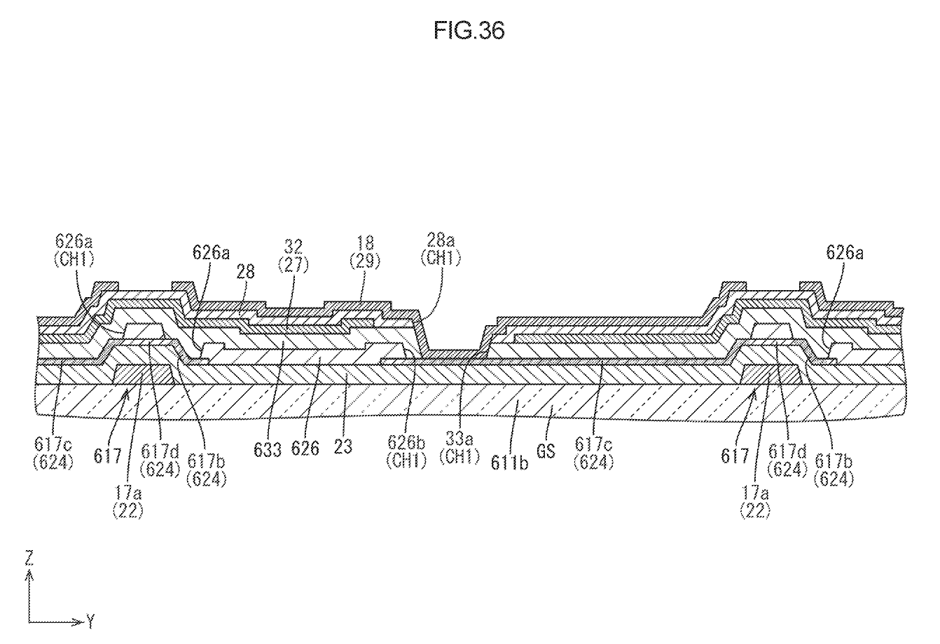

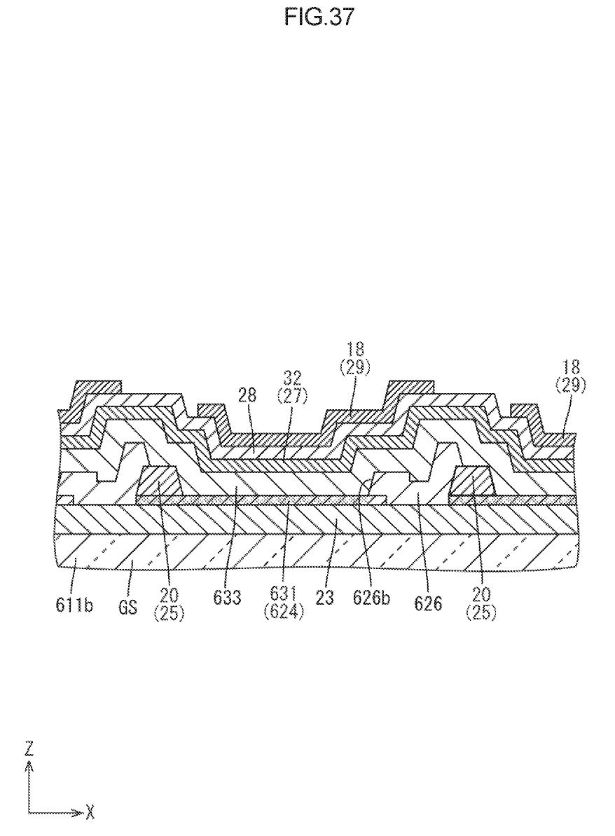

The line connector 631 including a source electrode 617b according to the present embodiment is formed by a low resistance region that is a part of an oxide semiconductor film 624 having a reduced resistance, as shown in FIGS. 35 to 37. The low resistance region of the oxide semiconductor film 624 functions as a conductor with a certain resistivity, similarly to the one described in the third embodiment. In FIGS. 36 and 37, the line connectors 631 (low resistance regions of the oxide semiconductor film 624) are illustrated with shading. The oxide semiconductor film 624 including the low resistance regions is made of light-transmitting conductive material that is substantially transparent. Therefore, the aperture ratio of pixels PX can be increased sufficiently by forming the line connectors 631 by a part of the oxide semiconductor film 624 (low resistance regions).

The line connectors 631 substantially entirely overlap source-side holes 626a in a first interlayer insulation film 626 as shown in FIGS. 35 and 37. A third interlayer insulation film 633 stacked on the upper side of the first interlayer insulation film 626 does not have third source-side holes 33b (see FIG. 23) described in the foregoing fourth embodiment. It covers exposed portions of the oxide semiconductor film 624 exposed through the source-side holes 626a in the first interlayer insulation film 626 and make direct contact with these exposed portions. The third interlayer insulation film 633 is made of silicon nitride as mentioned above and contains hydrogen as described in the fourth embodiment. Therefore, the hydrogen contained in the third interlayer insulation film 633 diffuses to the exposed portions of the oxide semiconductor film 624 through the source-side holes 626a in the first interlayer insulation film 626 and makes the resistance of the exposed portions lower. The exposed portions of the oxide semiconductor film 624 thus become substantially entirely low resistance regions and form the line connectors 631.

On the other hand, drain electrodes 617c are formed by low resistance regions that are parts of an oxide semiconductor film 624 having a reduced resistance, similarly to the fourth embodiment described above, as shown in FIGS. 35 and 36. Namely, since the drain electrodes 617c and the source electrodes 617b are both formed by low resistance regions of the oxide semiconductor film 624, the distance that needs to be secured between a drain electrode and a source electrode can be set shorter (specifically, as in the design shown in FIG. 19 and described in the foregoing third embodiment) as compared to if the drain electrodes 617c and source electrodes 617b were constructed from the same transparent electrode film. The channels 617d can therefore be made shorter, so that the characteristics of the TFTs 617 can be improved. Moreover, since the length of the channels 617d is determined by the distance between the two holes 626a and 626b formed in the first interlayer insulation film 626 similarly to the first embodiment and others described above, the length of the channels 617d is less likely to vary, which helps the TFT 617 exhibit its characteristics consistently. The line connectors 631 including the source electrodes 617b can be formed in addition to the channels 617d and drain electrodes 617c by patterning the oxide semiconductor film 624 during the production of the array substrate 611b, so that the production costs can be reduced.

As described above, according to the present embodiment, the drain electrode 617c is formed by a low resistance region that is a part of an oxide semiconductor film 624 having a reduced resistance. With the drain electrode 617c and the source electrode 617b of the line connector 631 both formed by low resistance regions of the oxide semiconductor film 624, the distance that needs to be secured between a drain electrode and a source electrode can be set shorter as compared to if the drain electrodes 617c and source electrodes 617b were constructed from the same transparent electrode film. The channels 617d can therefore be made shorter, so that the characteristics of the TFTs 617 can be improved.

### Eighth Embodiment

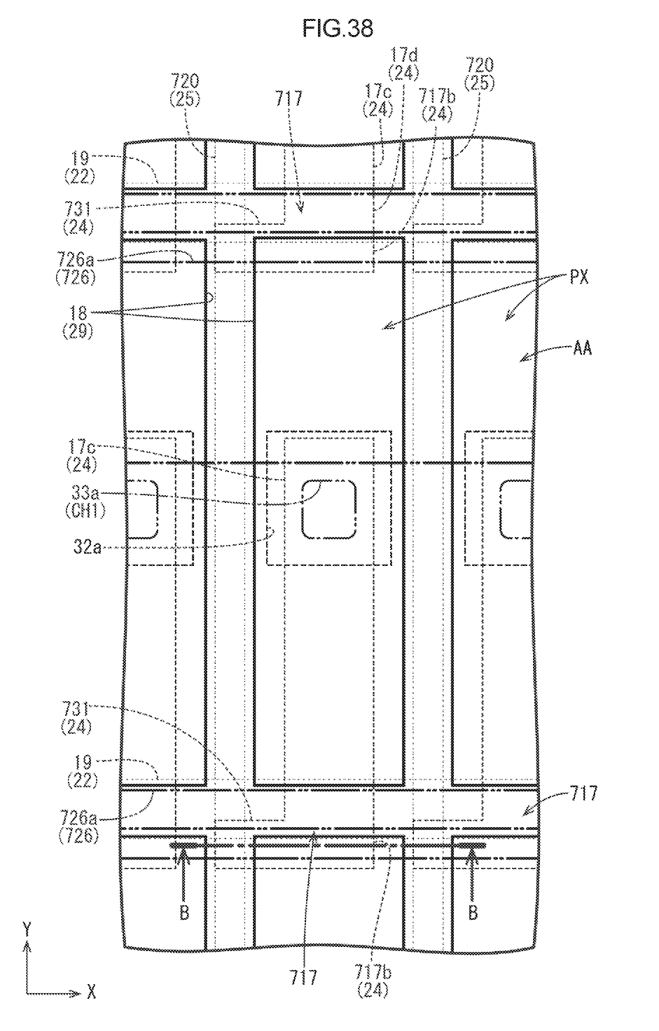

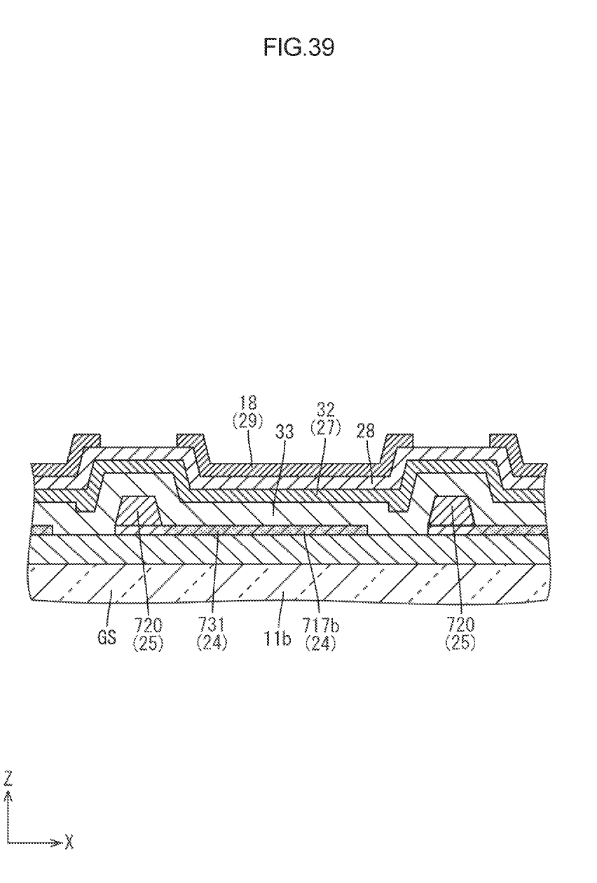

An eighth embodiment of the present invention will be described with reference to FIG. 38 or 39. The eighth embodiment illustrates an example wherein the area where a source-side hole 726a is formed is changed from that of the seventh embodiment described above. Repeated description of structures, effects and advantages similar to those of the seventh embodiment described above will be omitted.

The source-side hole 726a of a first interlayer insulation film 726 according to the present embodiment is formed in an area extending over adjacent pixels PX adjoining in the X-axis direction (direction in which a line connector 731 extends from a source line 720 toward a TFT 717), as shown in FIGS. 38 and 39. More specifically, the source-side hole 726a extends substantially over the entire length in the X-axis direction of a display area AA, in a belt-like shape crossing all the pixels PX aligned along the X-axis direction. A plurality of the belt-like source-side holes 726a are spaced at constant intervals in the Y-axis direction such that they collectively make stripes. The array pitch of the source-side holes 726a is substantially equal to the array pitch of the pixels PX in the Y-axis direction, and the number of the source-side holes 726a is equal to the number of pixels PX aligned along the Y-axis direction. If the source-side holes were formed in the first interlayer insulation film 726 discretely for the plurality of pixels PX aligned along the X-axis direction in the same number as that of the pixels PX, it would be necessary to set a constant interval between adjacent source-side holes. Such an interval need not be set if the source-side hole 726a that overlaps a source electrode 717b extends in the area over the pixels PX adjacent to each other in the X-axis direction. The array pitch of the pixels PX in the X-axis direction can thus be made smaller, which is favorable for achieving a higher resolution.

### Reference Example

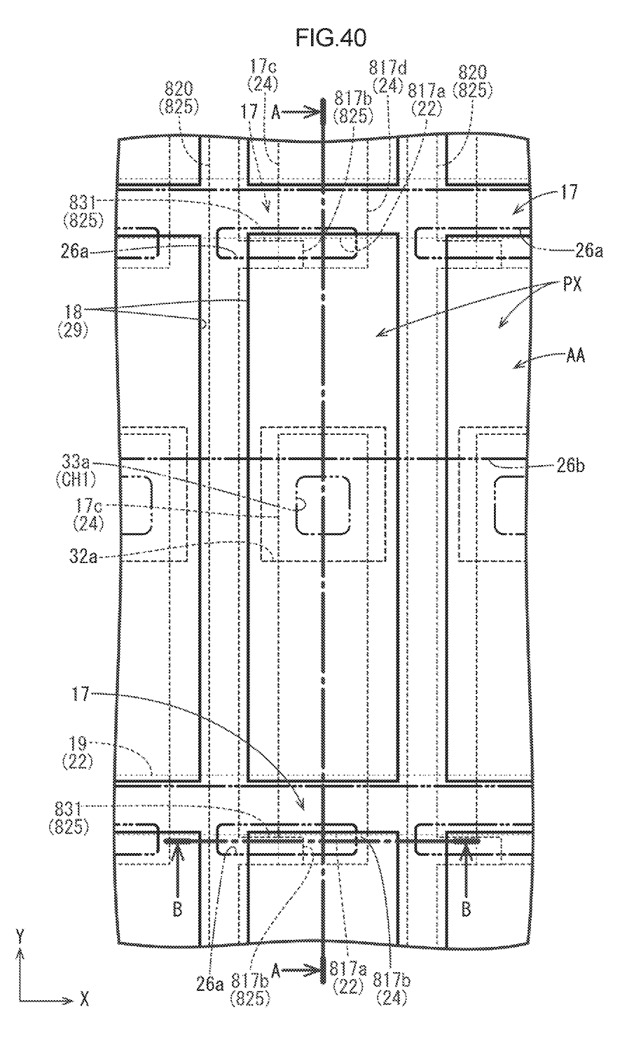

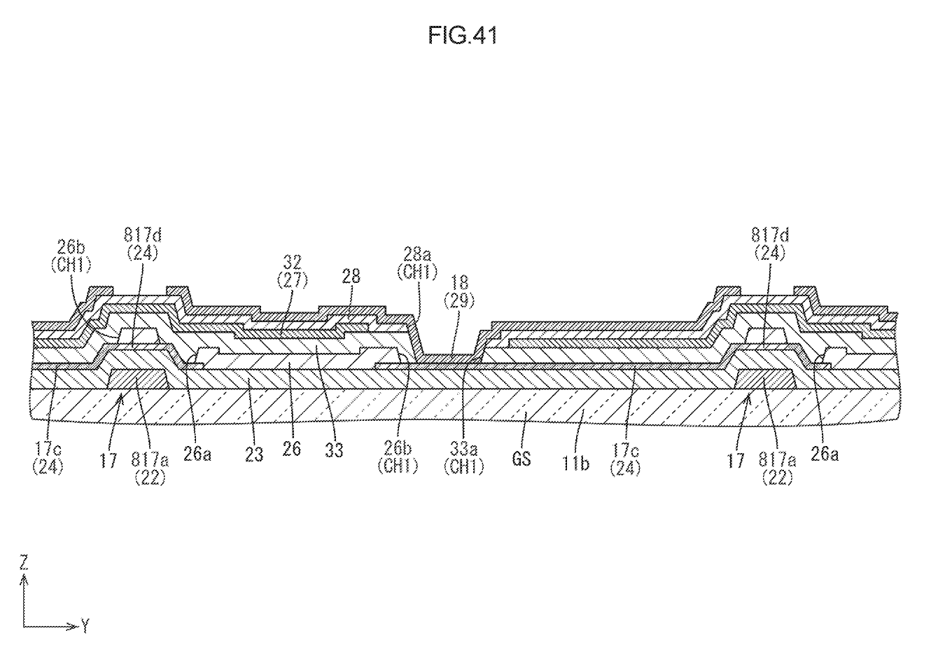

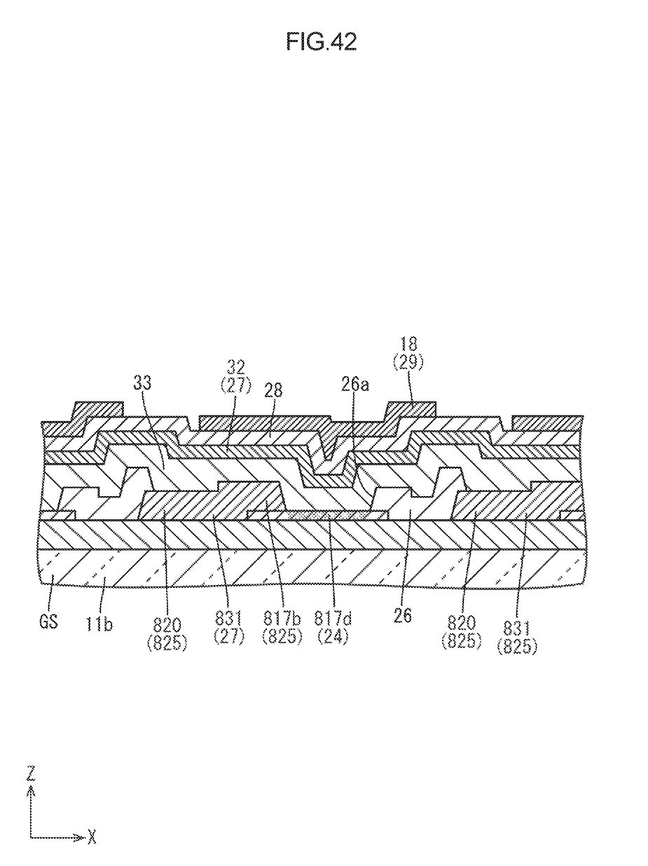

A reference example will be described with reference to FIGS. 40 to 42. This reference example illustrates a line connector 831 having a different configuration from that of the fourth embodiment described above. Repeated description of structures, effects and advantages similar to those of the fourth embodiment described above will be omitted.

The line connectors 831 according to this reference example are formed by branch portions branched from source lines 820 to extend along the X-axis direction as shown in FIGS. 40 to 42, the tips of the branch portions forming gate electrodes 817a and source electrodes 817b that overlap channels 817d. Namely, the line connectors 831 that contain the source electrodes 817b are constructed from the same second metal film 825 that forms the source lines 820.

### Other Embodiments

The present invention is not limited to the embodiments described above with reference to the drawings. The following embodiments, for example, are also included in the technical scope of the present invention.

(1) The transparent electrode films and oxide semiconductor films described in the foregoing embodiments as a light-transmitting, conductive material are not necessarily limited to a material having a value of 100% light transmittance or values close to 100% light transmittance, but may have values somewhat lower than 100% light transmittance, as long as it lets light pass through.

(2) As one modification of the first and second embodiments described above, the line connector (source electrode) and drain electrode may be constructed from the same second transparent electrode film that forms the common electrode.

(3) As one modification of the first and second embodiments and paragraph (1) described above, the drain electrode may be constructed from a transparent electrode film that is different from the transparent electrode film that forms the line connector (source electrode).

(4) While the line connector (source electrode) is constructed from the first transparent electrode film or second transparent electrode film in the foregoing first, second, and fourth to sixth embodiments, the line connector can also be constructed from a third transparent electrode film in an array substrate that includes the third transparent electrode film in addition to the first transparent electrode film and second transparent electrode film.

(5) While the drain electrode is constructed from the first transparent electrode film or second transparent electrode film in the foregoing first to third embodiments, the drain electrode can also be constructed from a third transparent electrode film in an array substrate that includes the third transparent electrode film in addition to the first transparent electrode film and second transparent electrode film.

(6) As one modification of the foregoing third, seventh, and eighth embodiments described above, the drain electrode may be formed by a low resistance region of an oxide semiconductor film, while the line connector (source electrode) is constructed from the first transparent electrode film or the second transparent electrode film.

(7) As one modification of the fourth to sixth embodiments described above, the line connector (source electrode) may be constructed from the same second transparent electrode film that forms the pixel electrode. The line connector can also be constructed from a third transparent electrode film in an array substrate that includes the third transparent electrode film in addition to the first transparent electrode film and second transparent electrode film.

(8) As one modification of the foregoing fourth to eighth embodiments described above, the drain electrode may be constructed from the same first transparent electrode film that forms the common electrode, or constructed from the same second transparent electrode film that forms the pixel electrode. The drain electrode can also be constructed from a third transparent electrode film in an array substrate that includes the third transparent electrode film in addition to the first transparent electrode film and second transparent electrode film.

(9) As one modification of the foregoing fifth embodiment described above, the areas where the third source-side holes are formed in the third interlayer insulation film can be changed as required. For example, the third source-side holes in the third interlayer insulation film may be formed in the same areas as those of the fourth and sixth embodiments described above.

(10) In each of the foregoing embodiments, the line connectors are connected to the source lines as well as form the source electrodes of TFTs. The present invention is applicable also to other cases, for example, where the line connectors are connected to the gate lines as well as form the gate electrodes of TFTs.

(11) In the fourth to eighth embodiments described above, the drain-side contact hole is positioned in the center in the X-axis and Y-axis directions of the pixel. Instead, the contact hole may be positioned on one side of the pixel in one or both of the X-axis direction and Y-axis direction.

(12) Specific areas or positions where various holes are formed in various interlayer insulation films can be changed as required in other ways than those in the embodiments described above.

(13) While the material for the second interlayer insulation film and third interlayer insulation film was illustrated as silicon nitride in various embodiments described above, other materials than silicon nitride can also be used. In this case, too, the material should preferably contain hydrogen. The specific material of the first interlayer insulation film can also be changed as required.

(14) In the third and fourth to eighth embodiments described above, one example was illustrated wherein hydrogen contained in the material of the second interlayer insulation film or third interlayer insulation film is diffused to the oxide semiconductor film through the drain-side holes and source-side holes of the first interlayer insulation film to make the resistance of the oxide semiconductor film lower. Instead, in the production process of the array substrate, for example, after the first interlayer insulation film is patterned to form the drain-side holes and source-side holes, a resistance reducing process such as plasma processing or vacuum annealing may be performed to make the resistance of the oxide semiconductor film lower through the drain-side holes and source-side holes. In this case, materials that do not contain hydrogen can be used as the material of the second interlayer insulation film or third interlayer insulation film.

(15) Specific metal used for the first metal film and second metal film can be changed as required in other ways than those of various embodiments described above. The stack structure of the first metal film and second metal film can be changed as required. More specifically, the number of stacks may be changed, or a single layer structure may be formed. Further, an alloy structure may be formed.

(16) Specific transparent electrode materials used for the first transparent electrode film and second transparent electrode film can be changed as required in other ways than those of various embodiments described above. More specifically, transparent electrode materials such as ITO (indium tin oxide) or ZnO (zinc oxide) can be used.

(17) In each of the embodiments described above, an array substrate having an oxide semiconductor film as a semiconductor film was illustrated. Other materials such as a CG silicon (continuous grain silicon), which is a type of polysilicon (polycrystalline silicon), or an amorphous silicon can also be used as the material of the semiconductor film.

(18) In each of the embodiments described above, the gate lines extend straight along the X-axis direction, without any recesses or protrusions on the side edges thereof. Instead, there may be some recesses or protrusions on the side edges of the gate lines. If the gate lines have protrusions on the side edges, the protrusions may form the gate electrodes partly or entirely.

(19) In each of the embodiments described above, the gate lines are arranged to overlap the light shields of the CF substrate substantially entirely. Instead, the gate lines may be arranged to overlap the light shields only partly, or may be arranged such as not to overlap the light shields.

(20) In the fourth to eighth embodiments described above, an array substrate having two transparent electrode films (first transparent electrode film and second transparent electrode film) in the VA mode liquid crystal panel was illustrated. The present invention is also applicable to array substrates having one transparent electrode film in the VA mode liquid crystal panel. In this case, the pixel electrodes may be formed by the single transparent electrode film, while auxiliary capacitance lines parallel to the gate lines may be formed by the first metal film, so that a capacitance is formed between the auxiliary capacitance lines and pixel electrodes to keep the potential of charged pixel electrodes for a predetermined period of time.

(21) In each of the embodiments described above, one example was illustrated wherein no etch stop layer is formed above the channels such that the lower end surface of the source regions on the channel side is arranged to contact the upper surface of the oxide semiconductor film. Instead, etch stop TFTs can be used, wherein an etch stop layer is formed above the channels.

(22) In each of the embodiments described above, a liquid crystal panel that operates in FFS mode or VA mode was illustrated. The present invention is also applicable to liquid crystal panels that operate in other modes such as IPS (in-plane switching) mode.

(23) In each of the embodiments described above, a COG liquid crystal panel having drivers directly mounted on the array substrate was illustrated. The present invention is also applicable to COF (chip on film) liquid crystal panel having drivers mounted on a flexible board that is mounted on the array substrate.

(24) In each of the embodiments described above, a liquid crystal panel was illustrated as having pixels composed of three colors, red, green, and blue. The present invention is also applicable to liquid crystal panels having pixels composed of four colors, with yellow in addition to red, green, and blue.

(25) While a vertical quadrilateral liquid crystal panel was illustrated in each of the embodiments described above, the present invention is applicable also to horizontal quadrilateral liquid crystal panels and square liquid crystal panels. The present invention is also applicable to liquid crystal panels of other shapes such as circular or elliptic.

(26) The present invention also includes devices that include a functional panel such as a touch panel or a parallax barrier (switch liquid crystal panel) stacked upon the liquid crystal panel described in each of the foregoing embodiments.

(27) In each of the embodiments described above, a transmissive liquid crystal display device having a backlight device as an external light source was illustrated. The present invention is also applicable to reflective liquid crystal display devices that display images using external light, in which case the backlight device can be omitted. The present invention is also applicable to semi-transmissive liquid crystal display devices.

(28) In each of the embodiments described above, TFTs are used as the switching devices of the liquid crystal display device. The present invention is also applicable to liquid crystal display devices that use other switching devices than TFTs (such as thin film diodes (TFDs)). The present invention is applicable not only to color liquid crystal display devices but also monochrome liquid crystal display devices.

(29) In each of the embodiments described above, a liquid crystal display device that uses a liquid crystal panel as the display panel was illustrated. The present invention is applicable also to display devices that use other types of display panels such as PDP (plasma display panel), organic EL panel, EPD (electrophoresis display) panel, MEMS (micro electro mechanical system) display panel, and the like.

### EXPLANATION OF SYMBOLS

11, 311: Liquid crystal panel (display panel)

11a, 311a: CF substrate (counter substrate)

11b, 211b, 311b, 611b: Array substrate (thin film transistor substrate)

17, 117, 217, 317, 417, 517, 617, 717: TFT (thin film transistor)

17a, 217a, 317a, 517a: Gate electrode (electrode)

17b, 117b, 217b, 317b, 417b, 517b, 617b, 717b: Source electrode (electrode)

17c, 217c, 317c, 517c, 617c: Drain electrode (electrode)

17d, 217d, 317d, 517d, 617d: Channel

18, 218, 318: Pixel electrode (first transparent electrode)

20, 120, 320, 420, 520, 720: Source line (line)

24, 224, 324, 524, 624: Oxide semiconductor film (semiconductor film)

26, 126, 226, 326, 426, 526, 626, 726: First interlayer insulation film (insulation film)

26a, 126a, 226a, 326a, 426a, 526a, 626a, 726a: Source-side hole (hole)

26b, 226b, 326b, 526b, 626b: Drain-side hole (hole)

27, 227, 327: First transparent electrode film

28, 228: Second interlayer insulation film (interlayer insulation film)

29, 229: Second transparent electrode film

30, 230: Common electrode (second transparent electrode)

31, 131, 231, 331, 431, 531, 631, 731: Line connector

32, 532: Auxiliary capacitance electrode (second transparent electrode)

33, 333, 433, 533, 633: Third interlayer insulation film (insulation film)

33a, 333a: Third drain-side hole (hole)

33b, 433b, 533b: Third source-side hole (hole)

327, 527: First transparent electrode film (second transparent electrode film)

329: Second transparent electrode film (first transparent electrode film)

PX: Pixel

1. A thin film transistor substrate comprising:
a line;
a thin film transistor including a plurality of electrodes; and
a line connector made of light-transmitting conductive material and connected to the line, the line connector including at least a portion forming one of the plurality of electrodes.

2. The thin film transistor substrate according to claim 1, further comprising:
a first transparent electrode constructed from a first transparent electrode film and connected to one of the plurality of electrodes of the thin film transistor; and
a second transparent electrode constructed from a second transparent electrode film overlapping the first transparent electrode film via an interlayer insulation film, and configured to form a capacitor or an electric field between the second transparent electrode and the first transparent electrode,
wherein the line connector is constructed from one of the first transparent electrode film and the second transparent electrode film.

3. The thin film transistor substrate according to claim 2, wherein
the thin film transistor includes a channel constructed from a semiconductor film,
the plurality of electrodes include:
a source electrode including at least a portion of the line connector and being connected to a first end of the channel, and
a drain electrode connected to a second end of the channel, and
the drain electrode is constructed from one of the first transparent electrode film and the second transparent electrode film from which the line connector is constructed.

4. The thin film transistor substrate according to claim 2, wherein:
the thin film transistor includes a channel constructed from an oxide semiconductor film;
the plurality of electrodes include:
a source electrode including at least a portion of the line connector and being connected to a first end of the channel; and
a drain electrode connected to a second end of the channel; and
the drain electrode includes a low resistance region that is a part of the oxide semiconductor film having a reduced resistance.

5. The thin film transistor substrate according to claim 4, wherein
the first transparent electrode is a pixel electrode partly overlapping the line connector,
the second transparent electrode is an auxiliary capacitance electrode that forms a capacitor between the auxiliary capacitance electrode and the pixel electrode to hold a potential charged at the pixel electrode, and
the line connector is constructed from the second transparent electrode film.

6. The thin film transistor substrate according to claim 1, wherein
the thin film transistor includes a channel constructed from an oxide semiconductor film,
the plurality of electrodes include:
a source electrode that is at least a portion of the line connector and connected to a first end of the channel; and
a drain electrode that is connected to a second end of the channel, and
the line connector includes a low resistance region that is a part of the oxide semiconductor film having a reduced resistance.

7. The thin film transistor substrate according to claim 6, further comprising:
a first transparent electrode constructed from a first transparent electrode film and connected to the drain electrode of the thin film transistor and
a second transparent electrode constructed from a second transparent electrode film overlapping the first transparent electrode film via an interlayer insulation film, and configured to form a capacitor or an electric field between the second transparent electrode and the first transparent electrode,
wherein the drain electrode is constructed from one of the first transparent electrode film and the second transparent electrode film.

8. The thin film transistor substrate according to claim 6, wherein the drain electrode includes a low resistance region that is a part of the oxide semiconductor film having a reduced resistance.

9. The thin film transistor substrate according to claim 1, wherein
the thin film transistor includes the channel constructed from the semiconductor film,
the plurality of electrodes include:
the source electrode that is at least a portion of the line connector and connected to the first end of the channel; and
the drain electrode that is connected to the second end of the channel, and
the thin film transistor substrate further comprises an insulation film disposed on an upper side of the semiconductor film and having holes at positions overlapping the source electrode and the drain electrode, respectively.

10. The thin film transistor substrate according to claim 9, further comprising a plurality of pixels including the thin film transistor and aligned at least along a direction in which the line connector extends from the line toward the thin film transistor,
wherein one of the holes in the insulation film overlapping the source electrode extends across an area between pixels adjacent to each other in an direction in which the one of the holes extends.

11. A display panel comprising:
the thin film transistor substrate according to claim 1; and
a counter substrate bonded to the thin film transistor substrate.
